(19) United States
(12) Patent Application Publication
(10) Pub. No.: US 2016/0330342 A1
(43) Pub. Date: Nov. 10, 2016

(54) IMAGE SENSOR UNIT, METHOD OF MANUFACTURING SAME, PAPER SHEET DISTINGUISHING APPARATUS, IMAGE READING APPARATUS AND IMAGE FORMING APPARATUS

(71) Applicant: CANON COMPONENTS, INC., Kodama-gun, Saitama (JP)

(72) Inventors: Junya KINOSHITA, Saitama (JP); Takashi CHIBA, Saitama (JP); Yuusuke KATO, Saitama (JP); Noboru TATSUISHI, Saitama (JP)

(21) Appl. No.: 15/105,724

(22) PCT Filed: Sep. 10, 2014
(86) PCT No.: PCT/JP2014/073978

§ 371 Date: Jun. 17, 2016

(30) Foreign Application Priority Data
Dec. 20, 2013 (JP) 2013-264514

(51) Int. Cl. H04N 1/03; H05K 1/11; B41J 2/01; H05K 1/18

(52) U.S. Cl. CPC H04N 1/03; H05K 1/181; H05K 1/111; B41J 2/01; H05K 2201/10106; H04N 2201/0094

(57) ABSTRACT

A sensor substrate (13) includes an insertion opening (131) for inserting a light source substrate (32), and a plurality of pads (111) that are arranged along the insertion opening (131). The plurality of pads (111) and an external connection terminal are connected through a solder, and a tip of the pads (111) reaches an opening edge of the insertion opening (131).

### TECHNICAL FIELD

The present invention relates to an image sensor unit and a method of manufacturing the same, as well as optical apparatuses equipped with the image sensor unit, typically, a paper sheet distinguishing apparatus, an image reading apparatus and an image forming apparatus.

### BACKGROUND ART

An image sensor unit that reads a bill or an original as an object of illumination is used in a paper sheet distinguishing apparatus or an image reading apparatus. A surface-mounting-type LED package is sometimes used as a light source of an illumination device of an image sensor unit. For example, in Patent Literature 1, a mounting structure is disclosed in which a sub-substrate is erected on a main substrate of a printed circuit board.

### CITATION LIST

### Patent Literature

Patent Literature 1: Japanese Laid-open Patent Publication No. 2007-123456

### SUMMARY OF THE INVENTION

### Technical Problem

In the aforementioned kind of apparatus, when mounting an electronic component on a substrate, or when connecting substrates together, a solder is used for connecting a terminal of the electronic component or a terminal portion that is referred to as a “pad” of a substrate. In this connection, with respect to the quality of soldering together these terminal portions, in particular the bonding strength of the solder is extremely important for the performance and properties of the actual product. Therefore, although it is necessary to provide a pad at a position that eliminates a gap with respect to a slit opening edge that is provided in the main substrate to thereby increase the bonding strength of the solder, it is difficult to eliminate such a gap for reasons such as the finishing accuracy of the slit and the accuracy of arranging (etching) the pads.

In view of the above described situation, an object of the present invention is to improve the bonding strength obtained with a solder and thereby increase the bonding strength between substrates.

### Solution to Problem

An image sensor unit according to the present invention is an image sensor unit that reads light emitted to an object of illumination, including: a light source substrate including an external connection terminal; a light source that is mounted on the light source substrate; a light guide that emits light towards the object of illumination; a light condenser that focuses light from the object of illumination; an image sensor that receives light that is focused by the light condenser, and converts the light to an electric signal; and a sensor substrate on which the light source substrate and the image sensor are mounted; wherein: the sensor substrate includes an insertion opening for inserting the light source substrate, and a plurality of pads arranged along the insertion opening; and a plurality of the pads and the external connection terminal are connected through a solder, and a tip of the pads reaches an opening edge of the insertion opening.

Further, the image sensor unit of the present invention has, in a tip portion of the pads, a burr clearance portion that is formed at least on either side or both sides in a width direction thereof.

Furthermore, the image sensor unit of the present invention has a resist layer that is coated onto a surface of the sensor substrate on which the pads are arranged, wherein a peripheral portion of the pads is covered by the resist layer.

Further, the image sensor unit of the present invention has a thinned-out region in which some of the pads that are arranged along the insertion opening are thinned out, and a lead wiring pattern that is formed in the thinned-out region.

Furthermore, in the image sensor unit of the present invention, the thinned-out region is set at an end side of the sensor substrate.

Further, a paper sheet distinguishing apparatus of the present invention is a paper sheet distinguishing apparatus that reads light from an object of illumination while relatively moving an image sensor unit and the object of illumination, wherein the image sensor unit is the image sensor unit described above.

An image reading apparatus according to the present invention is an image reading apparatus that reads light from an object of illumination while relatively moving an image sensor unit and the object of illumination, wherein the image sensor unit is the image sensor unit described above.

An image forming apparatus according to the present invention includes: image reading means that reads light from an object of illumination while relatively moving an image sensor unit and the object of illumination, and image forming means that forms an image on a recording medium; wherein the image sensor unit is the image sensor unit described above.

A method of manufacturing an image sensor unit according to the present invention is a method of manufacturing an image sensor unit that reads light emitted to an object of illumination and that includes: a light source substrate including an external connection terminal, a light source that is mounted on the light source substrate, a light guide that emits light towards the object of illumination, a light condenser that focuses light from the object of illumination, an image sensor that receives light that is focused by the light condenser, and converts the light to an electric signal, and a sensor substrate on which the light source substrate and the image sensor are mounted; the method of manufacturing including: previously setting a formation region for an insertion opening of the light source substrate on the sensor substrate, extending a tip portion of the pad as far as an inner side of the formation region for the insertion opening and forming the pad, and cutting the formation region for the insertion opening together with the tip portion of the pad by means of a cutting tool.

In the method of manufacturing the image sensor unit of the present invention, a burr clearance portion is formed at least in a downstream-side area in a feeding direction of the cutting tool in a tip portion on the insertion opening side of the pad.

In the method of manufacturing an image sensor unit of the present invention, a resist layer is coated onto a surface of the sensor substrate on which the pad is arranged, and a peripheral portion of the pad is covered by the resist layer.

The method of manufacturing an image sensor unit of the present invention thins out some of the pads that are arranged along the insertion opening, and forms a lead wiring pattern in the thinned-out region.

Furthermore, in the method of manufacturing an image sensor unit of the present invention, the thinned-out region is set at an end side of the sensor substrate.

### Advantageous Effects of Invention

According to the present invention, since there is no gap or the like between a pad and an insertion opening, the bonding strength of a solder can be improved and thus the bonding strength between a light source substrate and a sensor substrate can be increased.

### BRIEF DESCRIPTION OF DRAWINGS

FIG. 1 is a schematic exploded view schematically illustrating a configuration example of an illumination device.

FIG. 2A is an external perspective view schematically illustrating a configuration of one light source module.

FIG. 2B is an external perspective view schematically illustrating a configuration of another light source module.

FIG. 3 is a perspective view schematically illustrating a configuration example of the vicinity of an end in a main-scan direction of an illumination device.

FIG. 4 is a schematic exploded view illustrating a configuration example of an image sensor unit.

FIG. 5 is an external perspective view illustrating a configuration example of an image sensor unit.

FIG. 6 is a schematic sectional view showing an internal configuration in the vicinity of an end in a main-scan direction of an image sensor unit.

FIG. 7A is a view illustrating a state in which a light source substrate and a sensor substrate are connected through a solder.

FIG. 7B is a view illustrating an example of pads that are provided in rows on a lower surface of a sensor substrate.

FIG. 8 is a view illustrating an example of a case where there is a gap between the tips of pads of a sensor substrate and a long hole.

FIG. 9 is a view illustrating a state prior to routing processing of a pad that is formed on a lower surface of a sensor substrate.

FIG. 10 is a view illustrating a state after routing processing in the sensor substrate illustrated in FIG. 9.

FIG. 11A is a plan view illustrating an example of an area around a pad on which a resist layer is coated.

FIG. 11B is a sectional view along a line I-I in FIG. 11A.

FIG. 12 is a view for describing an action of a load that is applied to an area around a pad.

FIG. 13A is a plan view illustrating an example of an area around a pad on which a resist layer is not coated.

FIG. 13B is a sectional view along a line II-II in FIG. 13A.

FIG. 14 is a view illustrating an example of a missing-teeth arrangement pattern of pads that are arranged around a long hole in a sensor substrate.

FIG. 15 is a view illustrating an example of pads that are not arranged in a missing-teeth arrangement pattern.

FIG. 16 is a view illustrating an example of a different missing-teeth arrangement pattern of pads that are arranged around a long hole in a sensor substrate.

FIG. 17 is a schematic sectional view showing a configuration of a paper sheet distinguishing apparatus.

FIG. 18 is a schematic sectional view showing a configuration of a paper sheet distinguishing apparatus having a transmission illumination device.

FIG. 19 is a schematic sectional view showing a configuration of a paper sheet distinguishing apparatus having two sets of image sensor units.

FIG. 20 is an external perspective view schematically illustrating a configuration of a flatbed-type scanner.

FIG. 21 is a cross-sectional schematic view illustrating a configuration of a sheet-feed type scanner.

FIG. 22 is an external perspective view of an image forming apparatus.

FIG. 23 is a perspective view illustrated by extracting an image forming portion in a housing of an image forming apparatus.

### DESCRIPTION OF EMBODIMENTS

Embodiments that can apply the present invention will now be described in detail with reference to the drawings. The embodiments of the present invention provide an image sensor unit having an illumination device, and a paper sheet distinguishing apparatus, an image reading apparatus and an image forming apparatus which have the image sensor unit. In each of the drawings, three-dimensional directions are indicated by X, Y, and Z arrows. The X direction denotes a main-scan direction of the image sensor unit to which the illumination device is applied. The Y direction denotes a sub-scan direction of the image sensor unit. The Z direction denotes a vertical direction of the image sensor unit. In this case, the object of illumination side is taken as the upper side. The illumination device that is an embodiment of the present invention is installed in the image sensor unit and used. While moving relatively in the sub-scan direction with respect to the object of illumination, the image sensor unit emits light at the object of illumination by means of the illumination device, and reads an image of the object of illumination by means of reflected light or transmitted light thereof. Further, in the present invention, the term “light” refers to not only visible light, but also includes electromagnetic waves of wavelength bands other than visible light, such as ultraviolet light and infrared light.

(Illumination Device)

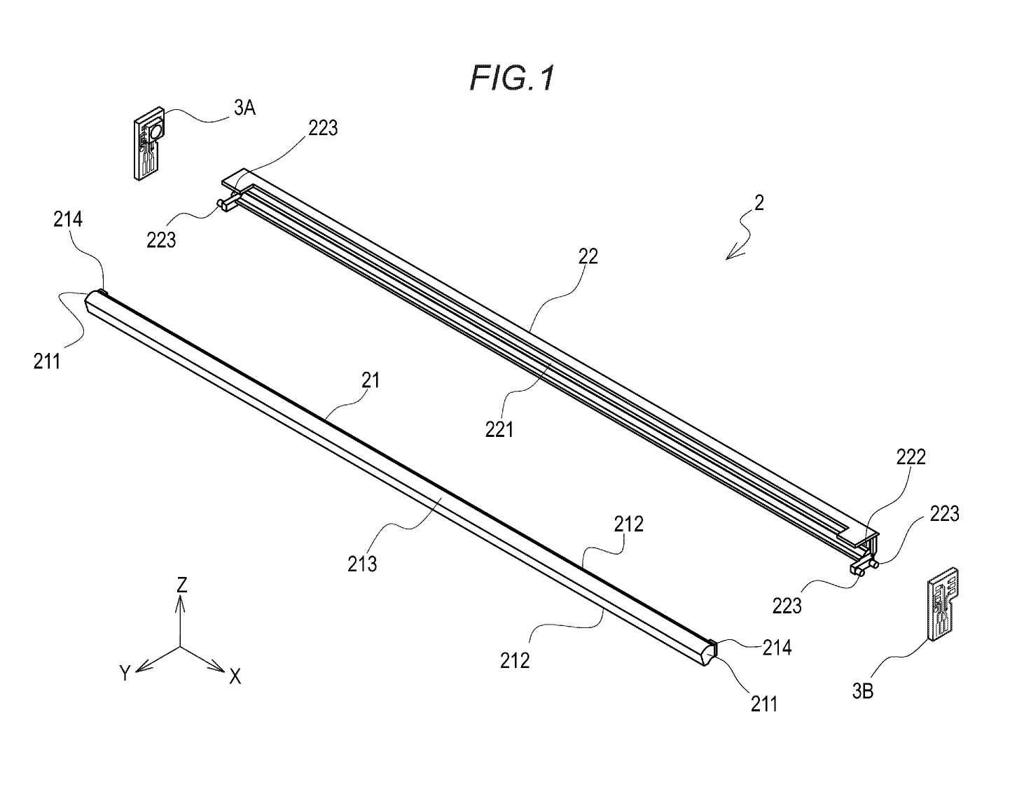

First, the configuration of the illumination device will be described. FIG. 1 is a schematic exploded view schematically illustrating a configuration example of an illumination device 2. The illumination device 2 illustrated in FIG. 1 includes a light guide 21, two light source modules 3A and 3B arranged at the two ends in a main-scan direction (longitudinal direction) of the light guide 21, respectively, and a light guide cover 22 that is attached to the light guide 21. Note that, as well as a configuration which has the two light source modules 3A and 3B at both ends of the light guide 21 as in the present example, a configuration may also be adopted which has a light source module at only one of the two ends.

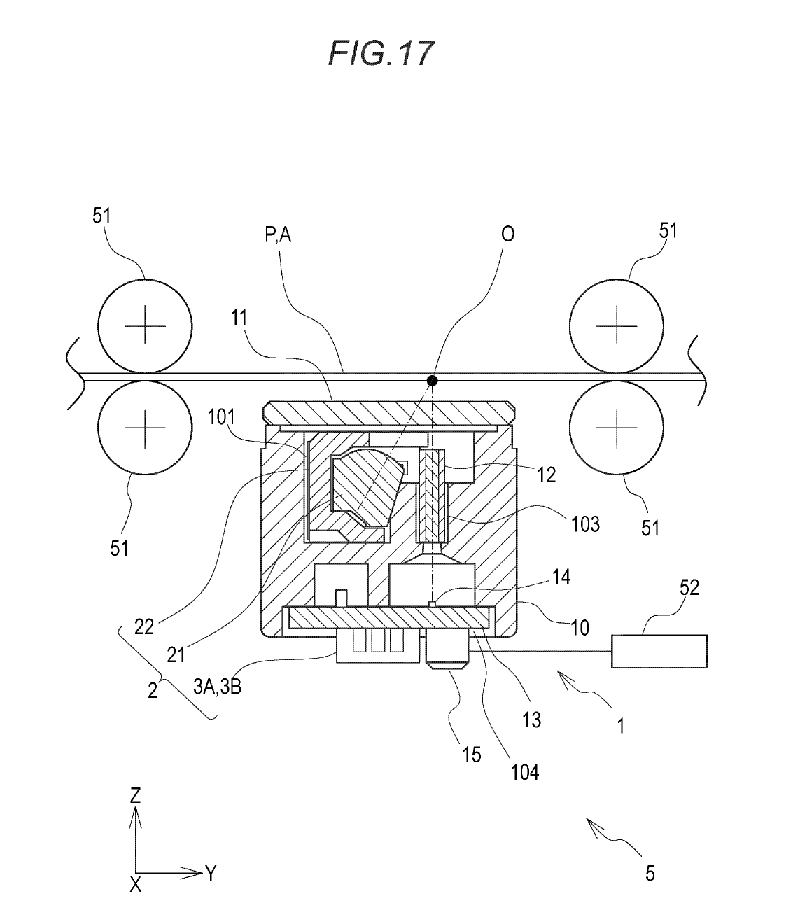

The light guide 21 is an optical member that shapes light emitted from the light source modules 3A and 3B into a line. The light guide 21 has an overall rod-like structure that is long and thin in the main-scan direction. The light guide 21, for example, is made of a transparent resin material, such as an acrylic resin, and is integrally formed by injection molding or the like. Light incident surfaces 211 upon which light that the light source modules 3A and 3B emit is incident are formed at the two end faces in the main-scan direction of the light guide 21, respectively. A light diffusing surface 212 and light emission surface 213 that have the shape of a long and thin band in the main-scan direction are provided on side surfaces of the light guide 21. The light diffusing surface 212 is a surface for reflecting and diffusing light incident from the light incident surface 211. For example, a prism-like structure for diffusing light is formed on the light diffusing surface 212. The light diffusing surface 212 may also be a structure in which a pattern for diffusing light is printed on the surface thereof. The light emission surface 213 is a surface that emits light that is incident from the light incident surface 211 towards an object of illumination P (see FIG. 17). In addition, engagement portions 214 for positioning the light guide 21 with respect to the light guide cover 22 are provided at the ends in the main-scan direction of the light guide 21. For example, a protrusion-like structure that protrudes in a sub-scan direction can be applied as the engagement portion 214.

The light guide cover 22 has a function of reflecting light and a function of improving the utilization efficiency of light. The light guide cover 22 has a rod-like structure that is long and thin in the main-scan direction, and a cross-sectional shape of a section thereof that is cut at a plane perpendicular to the main-scan direction is formed substantially in a “U” shape. A light reflection surface 221 is provided on the light guide cover 22. The light reflection surface 221 is a surface for reflecting light emitted to the outside from the light diffusing surface 212 of the light guide 21 to thereby cause the light to enter inside of the light guide 21 once more. A part or all of the surface inside the “U” shape of the light guide cover 22 serves as the light reflection surface 221. To realize such functions, the light guide cover 22 is formed by, for example, a material with a high light reflectance, such as polycarbonate mixed with titanium oxide powder. Note that, similarly to the light diffusing surface 212 of the light guide 21, the light reflection surface 221 is formed in a long and thin band shape that extends in the main-scan direction. In a state in which the light guide cover is attached to the light guide 21, the light reflection surface 221 covers the light diffusing surface 212 of the light guide 21, or faces the light diffusing surface 212 of the light guide 21.

Portions to be engaged 222 which are portions that the engagement portions 214 of the light guide engage with are provided in the vicinity of the ends in the main-scan direction (longitudinal direction) of the light guide cover 22. If the respective engagement portions 214 of the light guide are protrusions that protrude in the sub-scan direction, through-holes that penetrate the light guide cover 22 in the sub-scan direction or concave portions formed by recessing the light guide cover 22 in the sub-scan direction are applied as the portions to be engaged 222 of the light guide cover 22. In addition, positioning portions 223 for positioning the light source modules 3A and 3B that are described later are provided on the two end faces in the main-scan direction of the light guide cover 22.

Protrusions that protrude towards the outside in the main-scan direction from each of the two end faces of the light guide cover 22 are applied as the positioning portions 223. In the present embodiment, as the positioning portion 223, an example is illustrated in which two cylindrical protrusions are provided side by side with a predetermined interval therebetween in the sub-scan direction.

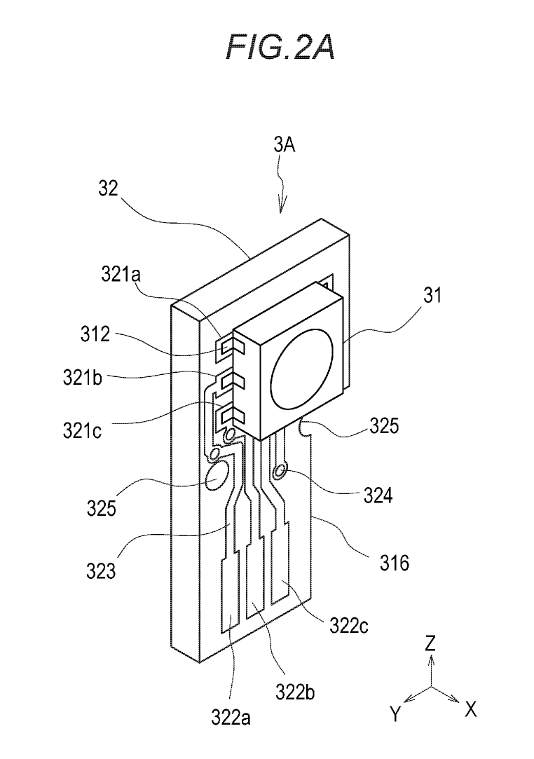

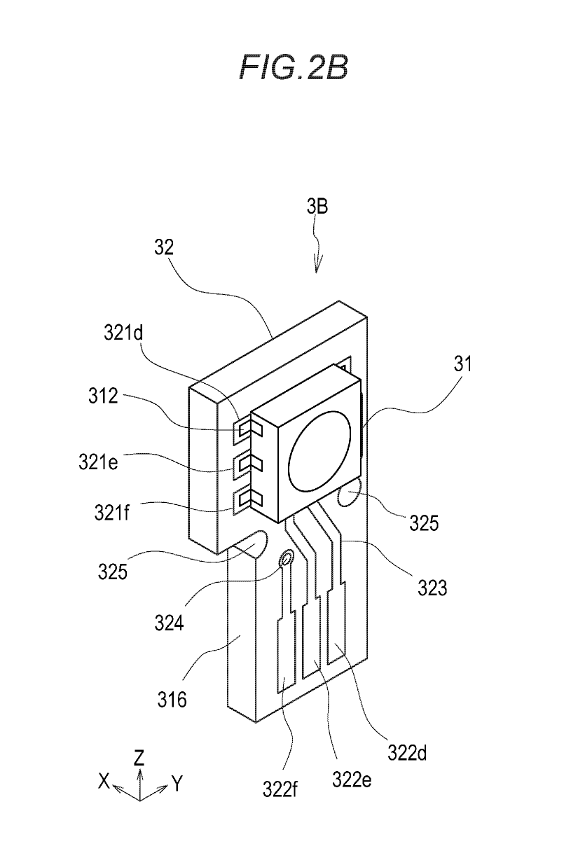

Next, the configuration of the light source modules 3A and 3B will be described. FIG. 2A and FIG. 2B are external perspective views that schematically illustrate the configuration of the two light source modules 3A and 3B. For the convenience of the description, one of the two light source modules is described as “first light source module 3A”, and the other of the two light source modules is described as “second light source module 3B”.

The overall configuration of the two light source modules 3A and 3B is as follows. The two light source modules 3A and 3B are constituted by a light source 31, and a light source substrate 32 on which the light source 31 is mounted. The light source substrate 32 is a two-sided-wiring type circuit board that is capable of mounting the light source 31 on both sides. The light source substrate has a common configuration for both of the two light source modules 3A and 3B. As illustrated in FIG. 2A and FIG. 2B, element pads 321a to 321f for mounting the light source 31 and that connect each of terminals 312 of the light source 31 (LED package), and external connection pads 322a to 322f for connecting to an external sensor substrate 13 are provided on the surface of the light source substrate 32. In the present embodiment, the external connection pads 322a to 322f are provided in the same number as the terminals 312 of the light source 31 to be mounted. Note that, a configuration may be adopted in which the external connection pads 322a to 322f are dispersed over both sides of the light source substrate 32, or a configuration may be adopted in which the external connection pads 322a to 322f are concentrated on only one side. In this case, a configuration is shown in which the six external connection pads 322a to 322f are provided in a manner in which three each of the external connection pads 322a to 322f are provided on the two sides of the light source substrate 32 (that is, half of the external connection pads 322a to 322f on each side).

Further, a wiring pattern 323 and a through-hole 324 that connect predetermined element pads 321a to 321b and predetermined external connection pads 322a to 322f are provided on the light source substrate 32. Further, the light source 31 that is mounted on the light source substrate 32 receives a power supply from outside through the external connection pads 322a to 322f, the wiring pattern 323 and through-hole 324, and the element pads 321a to 321f, and emits light. In addition, a positioning portion 325 for positioning the light guide 21 is formed in the light source substrate 32. A cut-out portion 316 is formed close to one side in the sub-scan direction at a lower portion of the light source substrate 32. Therefore, the light source substrate is formed in a substantially “L” shape in an inverted form as viewed in the main-scan direction.

The first light source module 3A is constituted by mounting a light source on a predetermined one-side surface (A surface) of the light source substrate 32, and the second light source module 3B is constituted by mounting a light source on a one-side surface (B surface) on the opposite side of the light source substrate 32. That is, the two light source modules 3A and 3B are separately made by mounting the light source 31 on the surfaces on each side of the light source substrate 32. Note that, although a common configuration of the light source 31 can be applied for the two light source modules 3A and 3B, different configurations of the light source 31 may also be applied with respect to the two light source modules 3A and 3B.

A surface-mounting-type LED package is applied as the light source 31. In the present embodiment, a surface-mounting-type LED package having three LED elements 311 (red (R), green (G), blue (B)) and six terminals 312 is applied as an example of the light source 31 in the image sensor unit 1 that is used in scanners 7A and 7B and an image forming apparatus 9 as image reading apparatuses that are described later. Further, in the image sensor unit 1 that is used in a paper sheet distinguishing apparatus 5 that is described later, for example, a surface-mounting-type LED package having four LED elements 311 (red (R), green (G), blue (B), infrared light (Ir)) and six terminals 312 is applied. In the present embodiment, the light source 31 (LED package) that is common to the two light source modules 3A and 3B is applied. Note that, this configuration is one example, and the light source 31 of the present invention is not limited to an LED package having this configuration.

According to this configuration, even when the light source 31 is mounted on either one of the A surface and the B surface of the light source substrate 32, power can be supplied to the light source 31 through the external connection pads 322a to 322f. Further, according to this configuration, the external connection pads 322a to 322f can be shared with respect to a case in which the light source 31 is mounted on the A surface and a case in which the light source 31 is mounted on the B surface.

The positioning portion 325 for positioning the light guide cover 22 is also provided on the light source substrate 32. In the present embodiment, as the positioning portion 325, a configuration is illustrated in which a through-hole and a notch into which the positioning portion 223 of the light guide cover 22 is fitted are applied (see FIG. 2A and FIG. 2B). When the positioning portion 223 of the light guide cover 22 is fitted into the positioning portion 325 of the light source substrate 32, the light source 31 is positioned at a position (position facing the light incident surface 211 of the light guide 21) that emits light towards the light incident surface 211 of the light guide 21.

The first light source module 3A is constructed by mounting the light source 31 on a predetermined one-side surface (for example, the A surface) among the A surface and the B surface of the light source substrate 32. Further, the second light source module 3B is constructed by mounting the light source 31 on a one-side surface (for example, the B surface) on the opposite side. According to the present embodiment configured in this manner, a two-sided-wiring type circuit board is applied for the light source substrate 32, and an LED package as the light source 31 is selectively mounted on either one of the one-side surfaces. By this means, the first light source module 3A and the second light source module 3B can be separately made by using the common light source substrate 32. Accordingly, the light source substrate 32 can be made common with respect to the two light source modules 3A and 3B. Therefore, the parts cost of the illumination device 2 can be reduced.

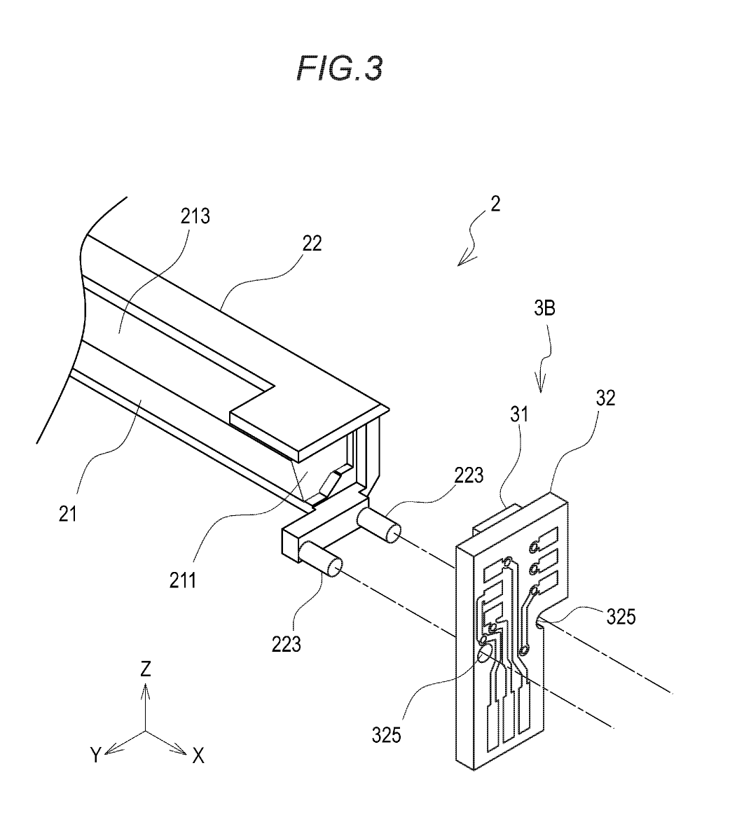

The assembly structure of the illumination device 2 is as follows. FIG. 3 is a perspective view schematically illustrating a state in which the light guide cover 22 is attached to the light guide 21, and illustrates the vicinity of an end in the main-scan direction. As illustrated in FIG. 3, the light guide cover 22 is attached to the light guide 21. At such time, the light guide cover 22 is positioned on the light guide 21 by causing the engagement portions 214 of the light guide 21 to engage with the portions to be engaged 222 of the light guide cover 22 (see FIG. 1). Further, when the light guide cover 22 is attached to the light guide 21, the light diffusing surface 212 of the light guide 21 and the light reflection surface 221 of the light guide cover 22 face (or contact) each other. Further, each of the two light source modules 3A and 3B are arranged so as to be able to radiate light onto each of the light incident surfaces 211 at the two ends in the main-scan direction of the light guide 21. At such time, the LED package as the light source 31 of the light source modules 3A and 3B, and the light incident surface 211 of the light guide 21 are positioned as a result of the positioning portions 223 of the light guide cover 22 being fitted into the positioning portions 325 of the light source substrate 32.

(Image Sensor Unit)

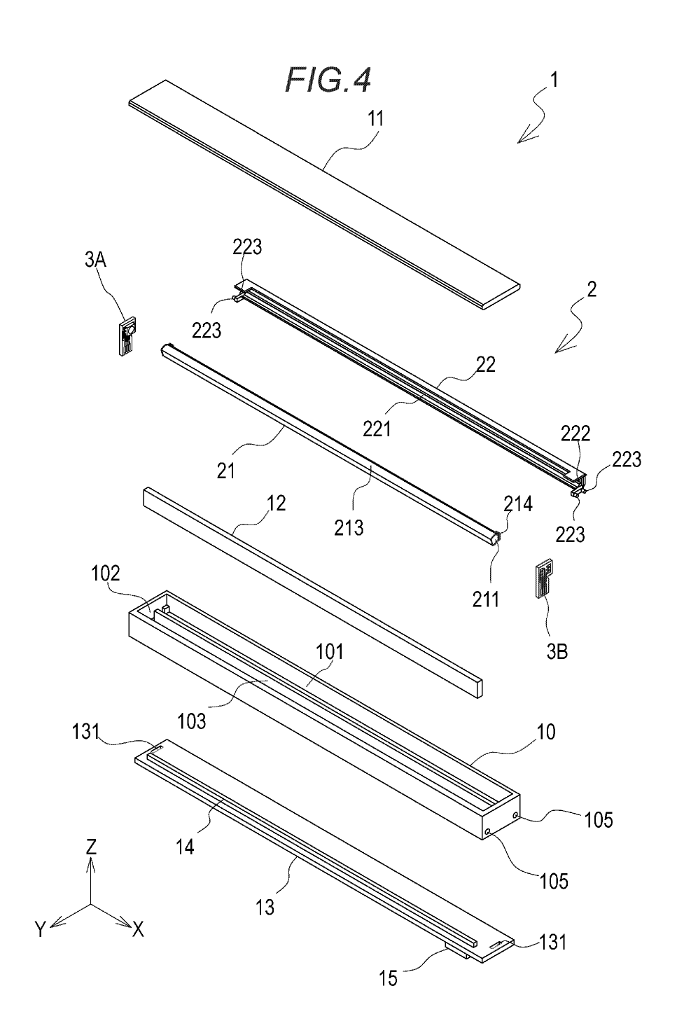

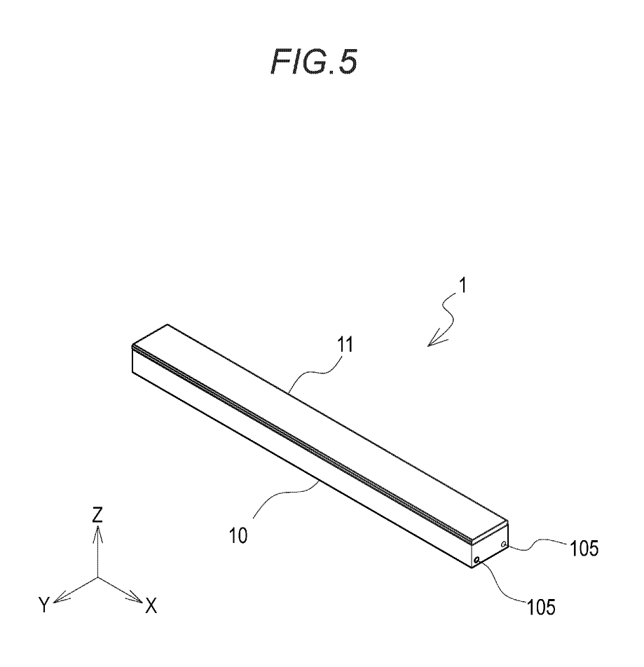

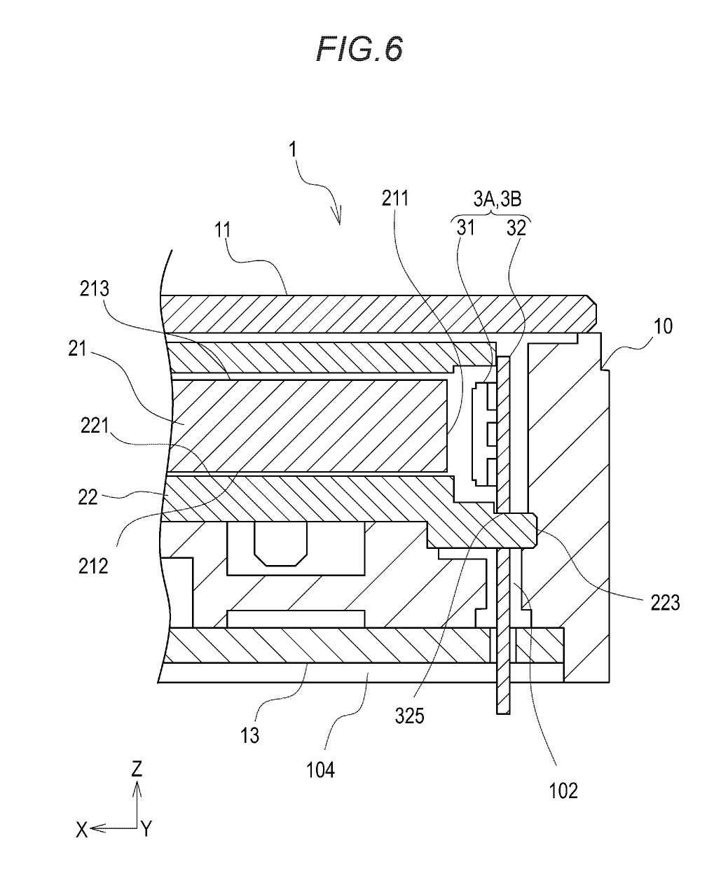

Next, the image sensor unit 1 to which the illumination device 2 is applied is described referring to FIG. 4 to FIG. 6. FIG. 4 is a schematic exploded view schematically illustrating a configuration example of the image sensor unit 1. FIG. 5 is an external perspective view illustrating a configuration example of the image sensor unit 1. FIG. 6 is a schematic sectional view showing an example of the internal configuration in the vicinity of an end in the main-scan direction of the image sensor unit 1. The image sensor unit 1 reads an object of illumination P by irradiating light onto the object of illumination P by means of the illumination device 2 and detecting light from the object of illumination P.

As illustrated in FIG. 4 to FIG. 6, as a whole, the image sensor unit 1 has a rod-like structure that is long in the main-scan direction. The image sensor unit 1 includes the illumination device 2, a frame 10, a cover member 11, a light condenser 12 and the sensor substrate 13. An image sensor 14 is provided on an upper face of the sensor substrate 13. A connector 15 for electrically connecting with the outside is mounted on a lower face of the sensor substrate 13. Note that the specific configuration of the connector 15 that is mounted on the lower face of the sensor substrate 13 is not limited as long as the configuration can connect the image sensor unit 1 to a predetermined equipment (for example, a circuit board) of the paper sheet distinguishing apparatus 5 that is described later (see FIG. 17) or the like to allow transmission and reception of power and electric signals.

The frame 10 is a housing of the image sensor unit 1. The frame 10 is formed by a light-blocking resin material that is colored in black. Polycarbonate can be applied as the resin material, for example. The frame 10 has a rectangular shape that is long in the main-scan direction when viewed from the upper surface. A light guide housing chamber 101 that is capable of housing the light guide 21 to which the light guide cover 22 is attached, and a light condenser housing chamber 103 that is capable of housing the light condenser 12 are formed in an upper portion of the frame 10. A circuit board housing chamber 104 that is capable of housing the sensor substrate 13 is formed in a bottom portion of the frame 10 (see FIG. 6). The light condenser housing chamber 103 and the circuit board housing chamber 104 are connected by an opening through which light can pass. In addition, a light source housing chamber 102 that is capable of housing each of the two light source modules 3A and 3B is formed at both ends in the main-scan direction of the frame 10. Further, screw holes 105 for attaching the image sensor unit 1 to another apparatus are formed in the two end faces in the main-scan direction of the frame 10. For example, the screw holes 105 are formed in the vicinity of both ends in the sub-scan direction, at positions that are at the lower portion of the two end faces in the main-scan direction.

The cover member 11 is arranged so as to cover the upper side of the frame 10. The cover member 11 is transparent, and is a rectangular plate-like member that is long in the main-scan direction when viewed from the upper surface. The cover member has a function of protecting the light guide 21 and the light condenser 12, and a function of coming into contact with the object of illumination P and keeping the object of illumination P flat. Note that, in a case where the image sensor unit 1 is applied to a flatbed-type image reading apparatus in which the object of illumination P does not directly contact the cover member 11 as described later, the cover member 11 need not be provided. However, it is preferable to install the cover member 11 therein to protect the image sensor unit 1 from the scattering of foreign matter and scratching. A member obtained by applying a hard coat to the surface of a transparent resin material such as glass, acrylic resin or polycarbonate so as to have a hardness that is equivalent to that of glass can be applied as the cover member 11.

The light condenser 12 is an optical member that forms an image of the light from the object of illumination P on the surface of the image sensor 14. For example, a rod-lens array is applied as the light condenser 12. A common rod-lens array has a configuration in which a plurality of imaging elements (rod lenses) of an erect equal magnification imaging type are linearly arranged in the main-scan direction. The specific configuration of the light condenser 12 is not limited as long as the imaging elements are arranged in a line. For example, the light condenser 12 may include imaging elements arranged in a plurality of lines. Various well-known optical members with a condensing function, such as various well-known micro-lens arrays, can be applied as the light condenser 12.

The sensor substrate 13 is a circuit board that has a rectangular structure that is long in the main-scan direction. The image sensor 14 is mounted on the upper surface of the sensor substrate 13, and the two light source modules 3A and 3B are also attached thereto. For example, as illustrated in FIG. 6, a long hole 131 into which the light source modules 3A and 3B can be respectively fitted is formed at both ends in the main-scan direction of the sensor substrate 13. These long holes 131 penetrate in the vertical direction, and extend in a slit shape in the sub-scan direction. The light source substrates 32 of the two light source modules 3A and 3B are respectively inserted into these long holes 131 that are insertion openings, and the external connection pads 322 of the light source substrate 32 and pads (omitted from the drawing) of a predetermined wiring pattern provided on the sensor substrate 13 are connected by a solder 110. By this means, the external connection pads 322a to 322f that are provided on the light source substrate 32 of the two light source modules 3A and 3B, and predetermined terminals of the connector 15 that is mounted on the lower surface of the sensor substrate 13 are electrically connected by the wiring pattern provided on the sensor substrate 13. Note that, as described above, differences in pin assignment between the two light source modules 3A and 3B are dealt with by means of the wiring pattern that is provided on the sensor substrate 13.

The image sensor 14 converts the light focused by the light condenser 12 to an electric signal. The image sensor 14 is mounted with a light receiving surface thereof facing upward so as to be capable of receiving light from the light condenser 12. The image sensor 14 is, for example, an image sensor IC array. The image sensor IC array includes a plurality of image sensor ICs that are linearly arranged and mounted on the surface of the sensor substrate 13 in the main-scan direction. The image sensor ICs are a plurality of light receiving elements (may also be called photoelectric conversion elements) corresponding to the resolution of reading by the image sensor unit 1. In this way, the image sensor 14 includes a plurality of image sensor ICs that are linearly arranged in the main-scan direction. The configuration of the image sensor 14 is not particularly limited as long as a plurality of image sensor ICs are linearly arranged. For example, the image sensor ICs may be arranged in a plurality of lines to form a staggered arrangement. The image sensor ICs included in the image sensor IC array as the image sensor 14 can be various conventional well-known image sensor ICs.

The assembly structure of the image sensor unit 1 is as follows. The light guide 21 to which the light guide cover 22 is attached, the light condenser 12 and the sensor substrate 13 are housed in the light guide housing chamber 101, the light condenser housing chamber 103 and the circuit board housing chamber 104 of the frame 10, respectively. The two light source modules 3A and 3B are each housed in the light source housing chamber 102 of the frame 10. A lower portion of the two light source modules 3A and 3B is fitted into the long hole 131 formed in the sensor substrate 13, and the external connection pads 322a to 322f of the light source substrate 32 are soldered to pads of a predetermined wiring pattern provided on the sensor substrate 13. In this way, the respective LED elements 311 of the light source 31 enter a state in which the LED elements 311 can receive a supply of power through the sensor substrate 13. The cover member 11 is attached to the upper side of the frame 10.

In this state, as illustrated in FIG. 6, the protrusion as the positioning portion 223 of the light guide cover 22 engages with the through-hole and notch as the positioning portion 325 of the light source substrate 32 of the light source modules 3A and 3B. In this way, the respective light sources 31 of the two light source modules 3A and 3B are positioned in a state in which the respective light sources 31 face the respective light incident surfaces 211 that are provided at the two end faces of the light guide 21. Consequently, light that the two light source modules 3A and 3B emit is incident on the light incident surfaces 211 of the light guide 21. When emitting light to the object of illumination P, in synchrony with each other, the two light source modules 3A and 3B turn on the LED elements 311 of each color and infrared light in sequence. The light emitted by the two light source modules 3A and 3B enters the light guide 21 from the light incident surface 211 of the light guide 21 and propagates through the inside while being reflected and diffused by the light diffusing surface 212. The light is emitted from the light emission surface 213 of the light guide 21 to a reading line O (see FIG. 17) of the object of illumination P.

The light condenser 12 and the image sensor face each other with a predetermined interval therebetween. The light condenser 12 focuses the reflected light from the reading line O of the object of illumination P on the light receiving surface of the image sensor 14. The image sensor 14 converts an optical image formed by the light condenser 12 to an electric signal.

The image sensor unit 1 periodically repeats the operation of radiating light at the object of illumination P and detecting reflected light. Based on the operation, the image sensor unit 1 reads an image of the object of illumination P. Further, in the paper sheet distinguishing apparatus 5, the image sensor unit 1 reads a visible light image of a predetermined pattern (for example, a hologram) provided on the object of illumination P and reads an infrared image of the object of illumination P.

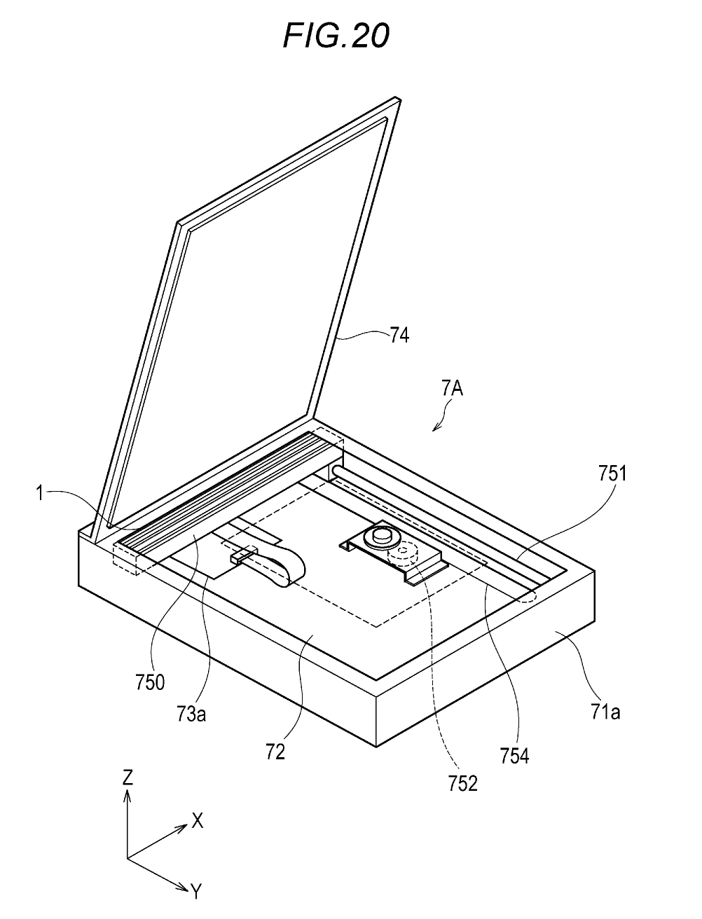

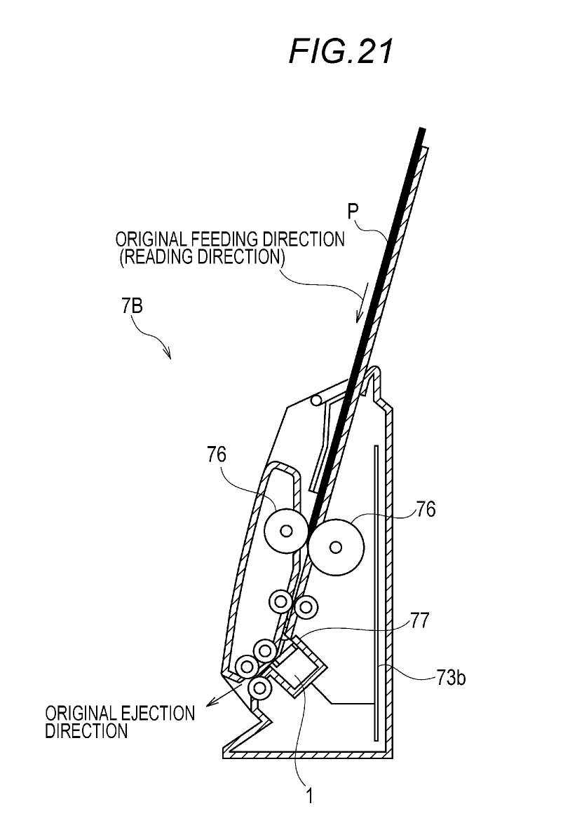

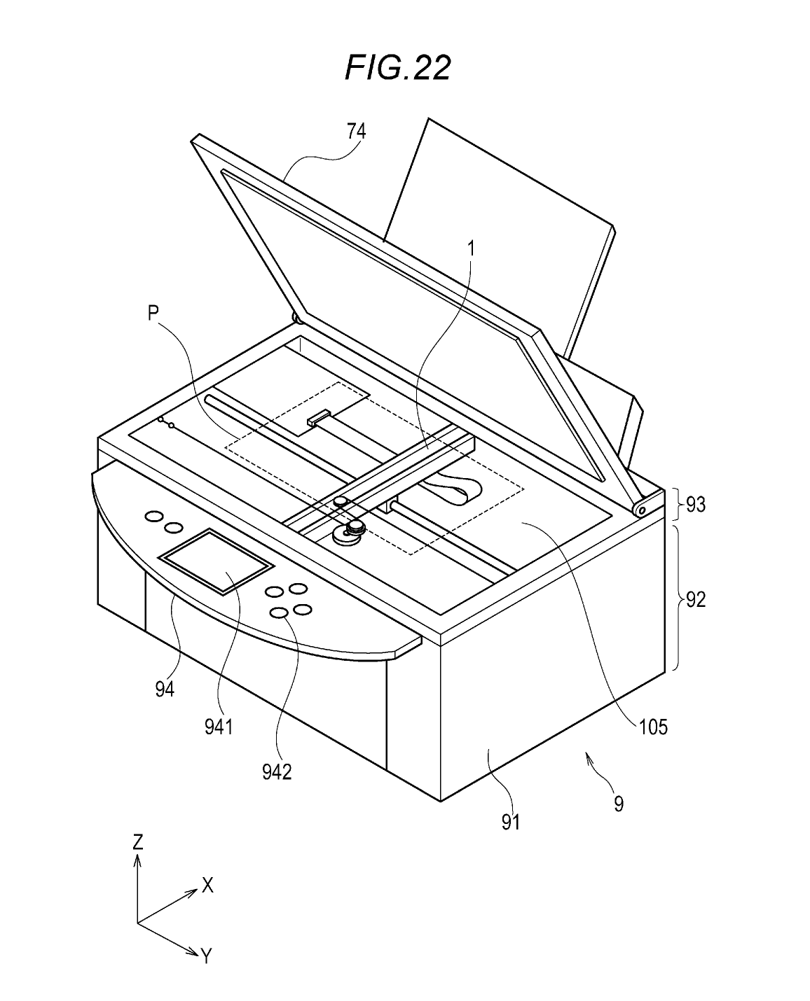

The frame 10 that is the housing of the image sensor unit 1 is attached by screws or the like to another apparatus such as the paper sheet distinguishing apparatus 5 or the image reading apparatus (scanner 7A and 7B (see FIG. 20 and FIG. 21)). For this purpose, the screw holes 105 for attachment are formed in the two end faces in the main-scan direction of the frame 10. As illustrated in FIG. 4 and FIG. 5, these screw holes 105 are formed at positions which are in the vicinity of the two ends in the sub-scan direction in the two end faces in the main-scan direction and which are in the vicinity of the bottom thereof. Therefore, inside the frame 10 (particularly, the light source housing chamber 102), thick portions protrude at positions that correspond to the screw holes 105 (specifically, a lower portion of four corners). Note that, because the light guide 21 and the light condenser 12 are arranged side by side in the sub-scan direction, the light guide 21 and the two light source modules 3A and 3B are arranged at positions that are deviated to be closer to one side in the sub-scan direction. Consequently, the positions that are closer to one side in the sub-scan direction of the lower portion of the light source substrate 32 come close to the four corners of the frame 10. Therefore, the cut-out portion 316 is formed close to one side in the sub-scan direction in the lower portion of the light source substrate 32 of the light source modules 3A and 3B of the present embodiment to avoid interference with regard to the thick portions that correspond to the screw holes 105. Accordingly, the light source substrate 32 is formed, as a whole, in a substantially “L” shape in an inverted form as viewed in the main-scan direction.

Therefore, in a configuration in which a circuit board with wiring on a single side is applied for the light source substrate 32, commonality of the light source substrate 32 cannot be achieved. That is, the two light source modules 3A and 3B are arranged so that the faces on the sides on which the light sources 31 are mounted face each other in a manner in which the light guide 21 is sandwiched therebetween. Therefore, when the two light source modules 3A and 3B are respectively viewed from the sides on which the light sources 31 are mounted, the cut-out portions 316 are located on opposite sides to each other with respect to the left and right sides in the two light source modules 3A and 3B. In a configuration in which a circuit board with wiring on a single side is applied for the light source substrate 32 of the two light source modules 3A and 3B in this way, because the light source substrate 32 must be made a shape that is line symmetric (symmetrical), and the light source substrate 32 cannot be used as it is for a common configuration.

In the present embodiment, the light source substrate 32 can be made common with respect to the two light source modules 3A and 3B. That is, the first light source module 3A is made by mounting the light source 31 on a predetermined one-side surface (for example, the A surface) of the light source substrate 32. Further, the second light source module 3B is made by mounting the light source 31 on the other one-side surface (for example, the B surface) of the light source substrate 32. In this way, in the two light source modules 3A and 3B, the light sources 31 are mounted on surfaces on opposite sides of the light source substrate 32. With this configuration, the shape is symmetrical when each of the two light source modules 3A and 3B are viewed from the sides on which the light sources 31 are mounted (see FIG. 2A and FIG. 2B). Accordingly, in the two light source modules 3A and 3B, commonization of the light source substrate 32 can be achieved.

Further, the dimensions of the light source substrate 32 in the sub-scan direction differ between the upper portion and lower portion thereof. The element pads 321a to 321f for mounting the light source 31 are provided at a portion with larger dimensions of the upper portion. Further, the external connection pads 322a to 322f for connecting to the sensor substrate 13 are provided at a portion with smaller dimensions of the lower portion. Note that, the positioning portion 325 is provided in the vicinity of a boundary between the portion with larger dimensions of the upper portion and the portion with smaller dimensions of the lower portion.

Although in the present embodiment a configuration is illustrated which avoids interference with thick portions that correspond to the screw holes 105, the present invention is not limited to this configuration. A configuration may also be adopted which avoids interference with a structure or member other than the thick portions. The present invention can be applied to a configuration (particularly, a configuration that is line-symmetric) in which the shape of the light source substrate 32 differs between the two light source modules 3A and 3B. In this case, commonality of the light source substrate 32 is easy.

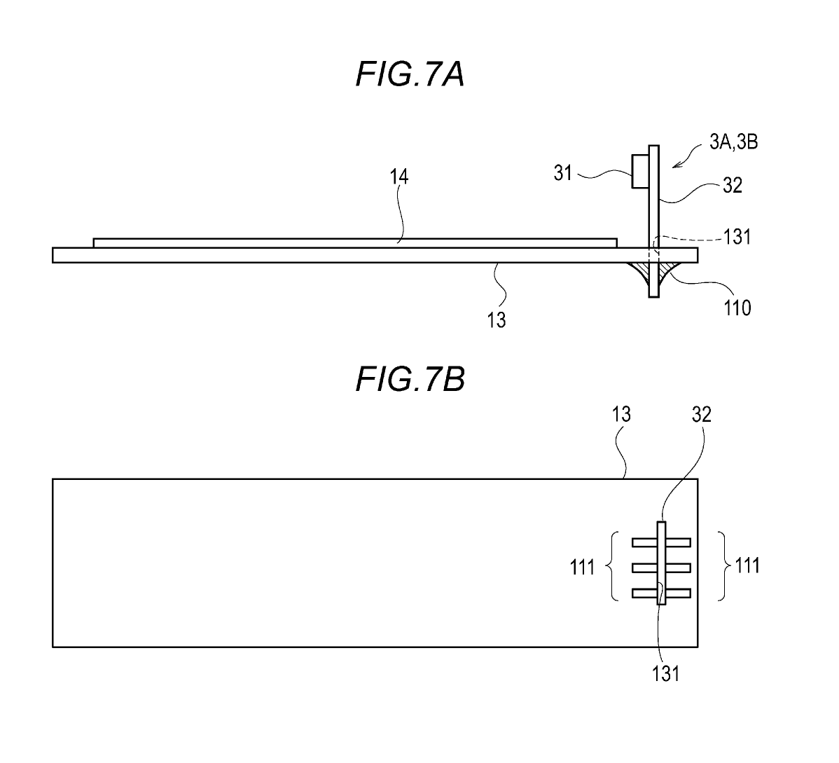

The present invention has a mounting structure in which a base end portion of the light source substrate 32 of each of the light source modules 3A and 3B is inserted into the corresponding long hole 131 (insertion opening) of the sensor substrate 13 as described above, and soldering of the external connection pads (external connection terminals) 322 to pads of the wiring pattern of the sensor substrate 13 is performed. FIG. 7A illustrates a state in which the light source substrate 32 and the sensor substrate 13 is connected through the solder 110. Note that, on the lower surface of the sensor substrate 13, a plurality of pads (or terminals) 111 are provided in rows along the long hole 131 as shown in FIG. 7B in correspondence with the external connection pads 322. These pads 111 are connected by soldering to respectively corresponding external connection pads 322. In the example illustrated in FIG. 7B, three of the pads 111 are arranged on each side of the long hole 131.

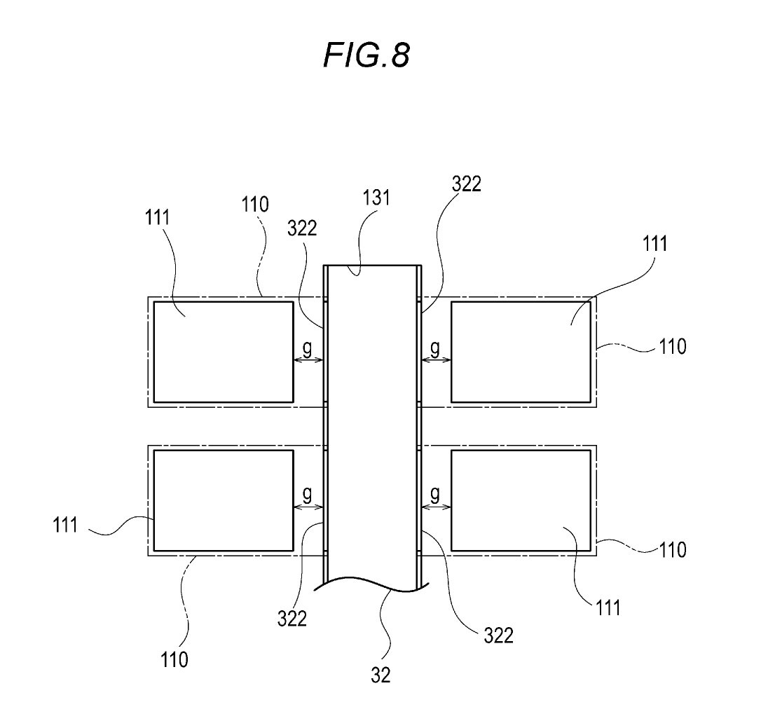

In this connection, when performing soldering, using the case of the present example for description purposes here, if there is a gap g (portion at which the pad 111 is not provided) between the tip of the relevant pad 111 and the opening edge of the long hole 131 of the sensor substrate 13 as schematically illustrated in FIG. 8, in practice the solder 110 does not function properly in at least the portion of the gap g. That is, the soldering is unstable in the gap g portion, and adequate electrical connectivity and bonding strength with respect to the corresponding external connection pad 322 is not necessarily secured through the solder 110. Note that, a processing error during routing processing that is performed using a cutting tool called a router end mill (hereunder, referred to as “router”) may be mentioned as an example of a cause of the occurrence of this kind of gap g. The plurality of pads 111 having predetermined dimensions and a predetermined shape are provided in rows on the sensor substrate 13 in advance, and the long hole 131 is formed by routing processing while feeding a router so as to move in a direction along the tips of the pads 111. The gaps g arises because the pads 111 cannot be disposed at positions that contact the opening edge of the long hole 131 due to a processing error during the routing processing.

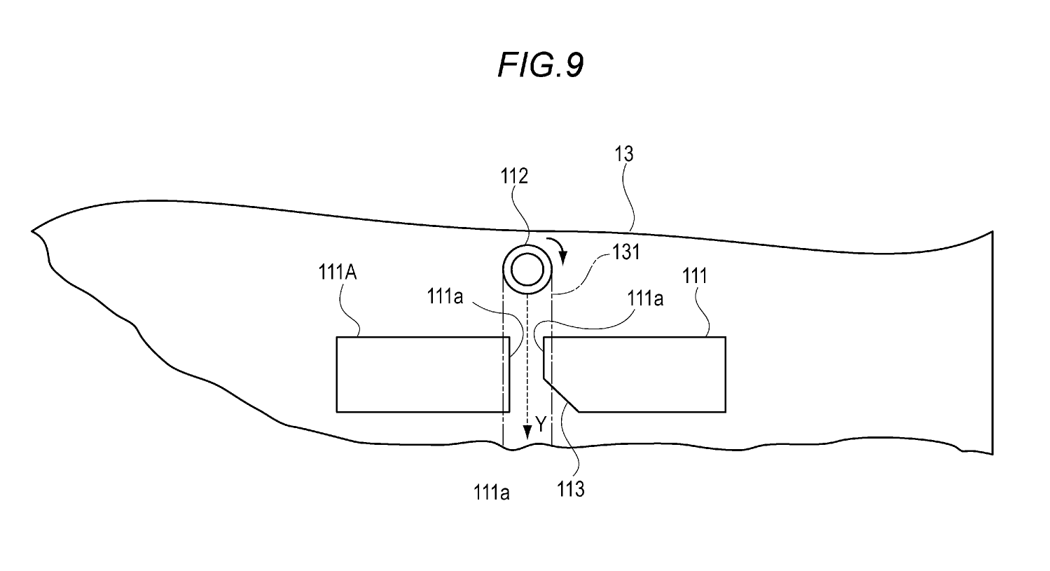

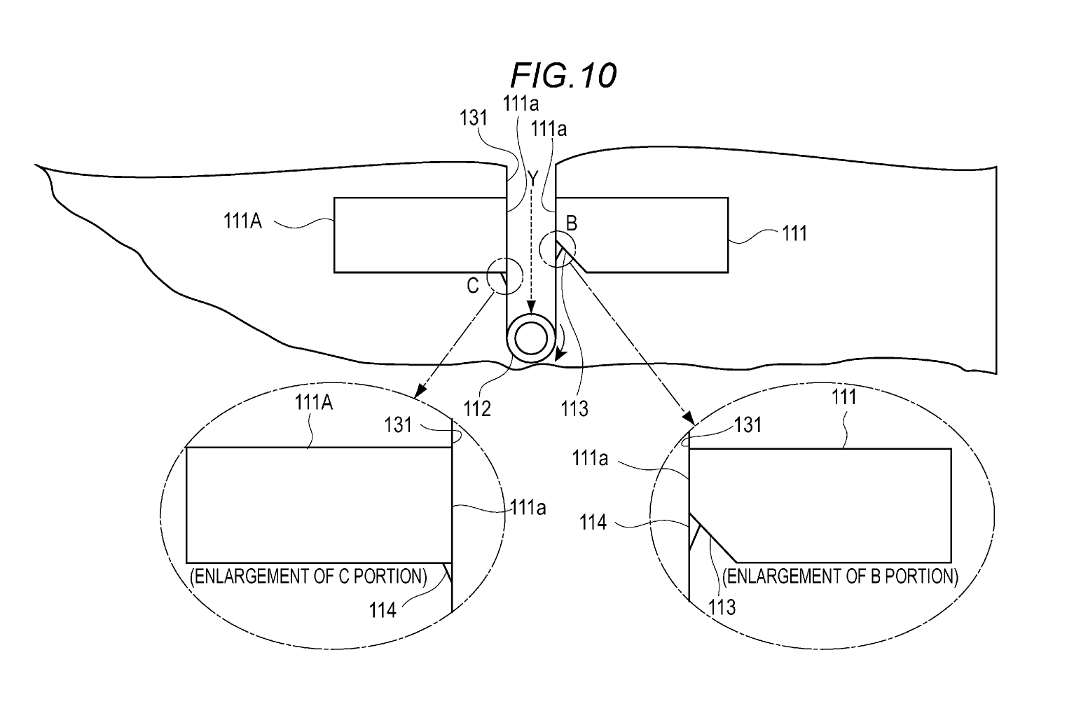

The present invention has, firstly, a mounting structure in which there are no gaps g between the pads 111 and the long hole 131 of the sensor substrate 13, so as to thereby stabilize the soldering. In FIG. 9, some of the pads 111 that correspond to FIG. 7B that are formed on the lower surface of the sensor substrate 13 are illustrated in a state prior to performing routing processing. FIG. 10 illustrates a state after performing routing processing with respect to the sensor substrate 13 shown in FIG. 9. In both FIG. 9 and FIG. 10, comparative examples with respect to the present invention are jointly illustrated on the left side of the drawings. In FIG. 9, a position or region at which the long hole 131 is formed in the sensor substrate 13 is set in advance as indicated by alternate long and short dashed lines, that is, the long hole 131 has a predetermined length along the direction (Y direction) in which the pads 111 are provided in rows. While rotating, a router 112 starts processing from outside of the region in which the pads 111 are arranged, and is fed at a predetermined speed in the Y direction to thereby form the long hole 131.

As described above, the plurality of pads 111 are provided in rows in advance in the Y direction on the sensor substrate 13, and in this case, as shown in FIG. 9, tip portions 111a of the pads 111 are formed to extend as far as the inside of the long hole 131 that is to be formed thereafter. That is, the tip portions 111a of the pads 111 are formed in a manner in which the tip portions 111a overlap with the inner region of the long hole 131. It is sufficient that the amount or length by which the tip portions 111a of the pad 111 overlap in this way is enough to ensure that the tip portions 111a extend as far as the inner region of the long hole 131 and to secure a cutting margin at the time of routing processing, and it is not necessary to made the tip portions 111a longer than required.

Further, in the present invention, at least on a downstream side in the feeding direction of the router 112 (Y direction) of a side-edge portion of the tip portion 111a of the pad 111, a cut-out portion 113 is provided so as to face the long hole 131. Although in the example illustrated in FIG. 9 the cut-out portion 113 has a roughly triangular shape in plan view, the specific shape thereof is arbitrarily selectable. The cut-out portion 113 acts as a clearance for burrs that are described later that are produced by the routing processing, and as long as a burr clearance function is secured, in terms of the relation with the stability of soldering, it is good for the cut-out portion 113 to be as small as possible. Note that, the cut-out portion 113 can also be provided on the upstream side in the feeding direction of the router 112, or can be provided on both the upstream and downstream sides.

As described above, the long hole 131 is formed by starting to feed the router 112 while causing the router 112 to rotate as shown in FIG. 10 with respect to the sensor substrate 13 on which the pads 111 are formed. By performing the routing processing for the long hole 131, the tip portions 111a of the pads 111 that extended as far as the inside of the long hole 131 as shown in FIG. 9 are simultaneously cut and removed. As a result of the process to form the long hole 131, the pads 111 reach the opening edge of the long hole 131, and therefore the aforementioned gaps g (FIG. 8) do not arise any more.

According to this method of manufacturing an image sensor unit of the present invention, an insertion opening for the light source substrate 32 in the sensor substrate 13, that is, the formation region of the long hole 131, is set in advance, and the pads 111 are formed in a manner in which the tip portions 111a of the pads 111 are extended as far as the inside of the formation region for the insertion opening. Thereafter, the formation region of the insertion opening is cut together with the tip portions 111a of the pads 111 by the router 112 that is a cutting tool.

Further, in this case, the cut-out portion 113 as a burr clearance portion is formed in the tip portion 111a at the long hole 131 of the pad 111, particularly in at least a downstream-side area in the feeding direction of the cutting tool.

The pads 111 are connected by the solders 110 to the external connection pads 322 of the light source substrate 32 that is inserted into the long hole 131 as described above, and because there are no gaps g in the mounting structure of the present invention, the soldering can be stably and properly performed. As a result, the electrical connectivity and bonding strength with the external connection pad 322 improves.

In addition, when performing the routing processing for the long hole 131, as illustrated in FIG. 10, although extremely small, burrs 114 arise at a cutting edge of the tip portion 111a of the pads 111. Although the burrs 114 extend out towards the feeding direction (Y direction) of the router 112 from the cutting edge of the tip portion 111a, the burrs 114 are formed only in the inner region of the cut-out portion 113, that is, the burrs 114 do not protrude to the outside in the width direction of the pads 111. Therefore, even if the burrs 114 arise, because the burrs 114 remain within the range of the region of the relevant pad 111, the risk of the relevant burr 114 contacting an adjacent pad 111 is reduced, thus contributing to realizing appropriate soldering. Although there is a demand to make the pads 111 more minute and to make the pitch at which the pads 111 are arranged an extremely small pitch accompanying miniaturization of this kind of device or apparatus, the relevant demand can be effectively met by eliminating the extrusion of the burrs 114 that are inhibiting factors with respect to such demands.

In this connection, in the case of a pad 111A that does not have the cut-out portion 113 as illustrated in FIG. 9 and FIG. 10, the burr 114 that arises during routing processing protrudes to the outside in the width direction from the cutting edge of the tip portion 111a of the pad 111A. There is a risk that the burr 114 that protrudes in this manner will contact an adjacent pad, and in that state the burr 114 will inevitably represent a disadvantage in terms of achieving proper soldering and miniaturization as described above.

The cut-out portion 113 provided in the pad 111 is not limited to the downstream side in the feeding direction of the router 112, and may be provided on the upstream side of the router 112 depending on the processing circumstances. That is, locations at which the cut-out portion 113 is provided may be combined depending on the downstream side in the feeding direction of the router 112, the downstream side in the rotation direction of the router 112, the number of passes of the router 112 during the processing or the like. In these cases also, to secure as large a contact area as possible between the pad 111 and the solder 110, it is favorable that the cut-out portion 113 is made as small as possible while still eliminating the protrusion of the burrs 114.

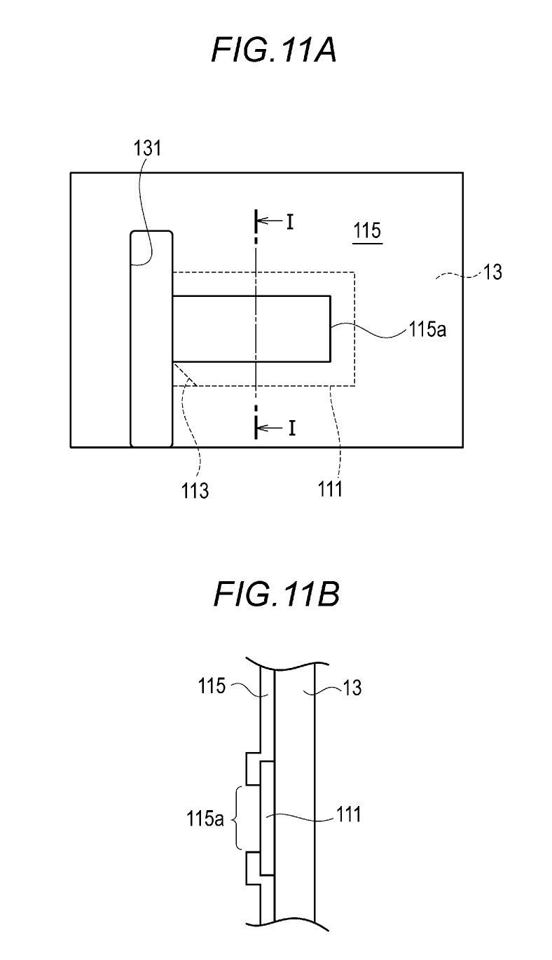

Next, an example having a mounting structure that is effective for strengthening bonding of the pads 111 to the sensor substrate 13 in the image sensor unit 1 of the present invention will be described. As shown in FIG. 11A and FIG. 11B, a resist layer 115 is coated onto the undersurface of the sensor substrate 13 on which the pads 111 are arranged. In the illustration in FIG. 11A and FIG. 11B also, a part of the pads 111 are shown, and a plurality of the pads 111 are provided in rows along the long hole 131. Similarly to the case described above, a configuration is adopted in which the base end portion of the light source substrate 32 is inserted into the long hole 131 (see FIG. 7A and FIG. 7B). According to the present invention, in particular, a peripheral portion (excluding the side of an edge that faces the long hole 131) of the pad 111 is covered by the resist layer 115. More specifically, the peripheral portion of the pad 111 is covered in a roughly frame-like shape by the resist layer 115, and only an inner region of the frame that corresponds to an opening 115a of the resist layer 115 is exposed to the outside. Note that, the exposed portion of the pad 111 approximately corresponds to a normal pad area.

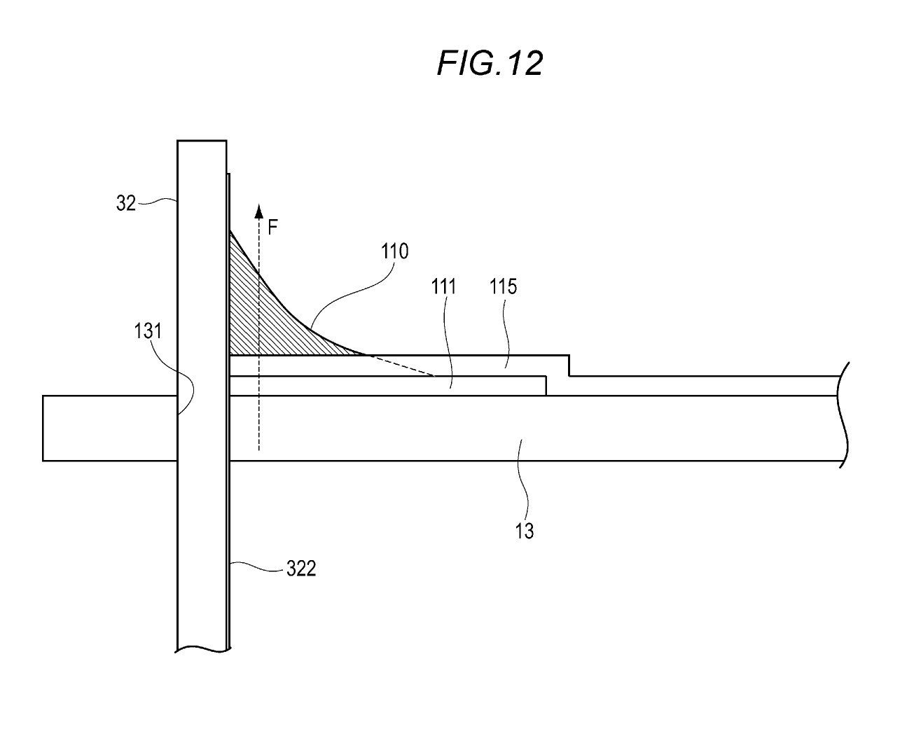

Similarly to the case described above, as shown in FIG. 12, the external connection pad 322 of the light source substrate 32 that is inserted into the long hole 131 and the pad 111 are connected to each other by the solder 110. Only one side of the long hole 131 is shown in FIG. 12. By covering the peripheral portion of the pad 111 with the resist layer 115, a structure is realized in which the bond strength with respect to the sensor substrate 13 of the pad 111 is increased and the bonding thereof is strengthened, and it is difficult for the pad 111 to come unstuck from the sensor substrate 13. As described later, the image sensor unit 1 is installed in an optical apparatus such as a paper sheet distinguishing apparatus or an image reading apparatus and used. Accompanying installation or the like of the image sensor unit 1 into such an optical apparatus, or due to vibrations or the like during use of the apparatus, in some cases a load F as shown in FIG. 12 is applied around the pads 111. Peeling off of the pads 111 with respect to the load F can also be suppressed, and appropriate operation of the apparatus can be secured and maintained. In addition, peeling off of the pads 111 can be suppressed when forming the long hole 131 by the routing processing.

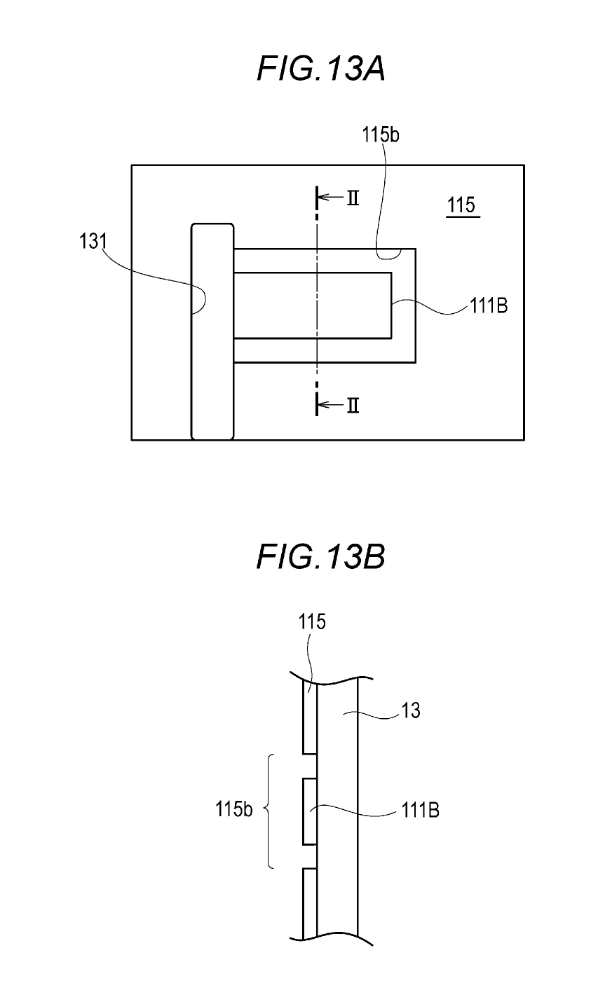

In this connection, conventionally, as shown in FIG. 13A and FIG. 13B, a pad 111B is not covered by the resist layer 115, that is, all of the pad 111B is exposed to outside within the opening 115b of the resist layer 115. Unlike the present invention, in the case of the pad 111B that is not reinforced in any way by coating of the resist layer 115, there is a risk that the pad 111B will peel off from the sensor substrate 13 due to the action of the load F as described above, and in that state will constitute a factor that inhibits the strength of soldering or the like.

While a detailed illustration has been described in detail for this example also, in this case a configuration is adopted so that the aforementioned gap g does not arise between the pads 111 and the long hole 131, and furthermore, as illustrated in abbreviated form in FIG. 11A, the aforementioned cut-out portion 113 can be formed with respect to the pad 111. In this case, the cut-out portion 113 is covered by the resist layer 115, and an effective area of the pad 111 with respect to the solder 110 can be effectively secured.

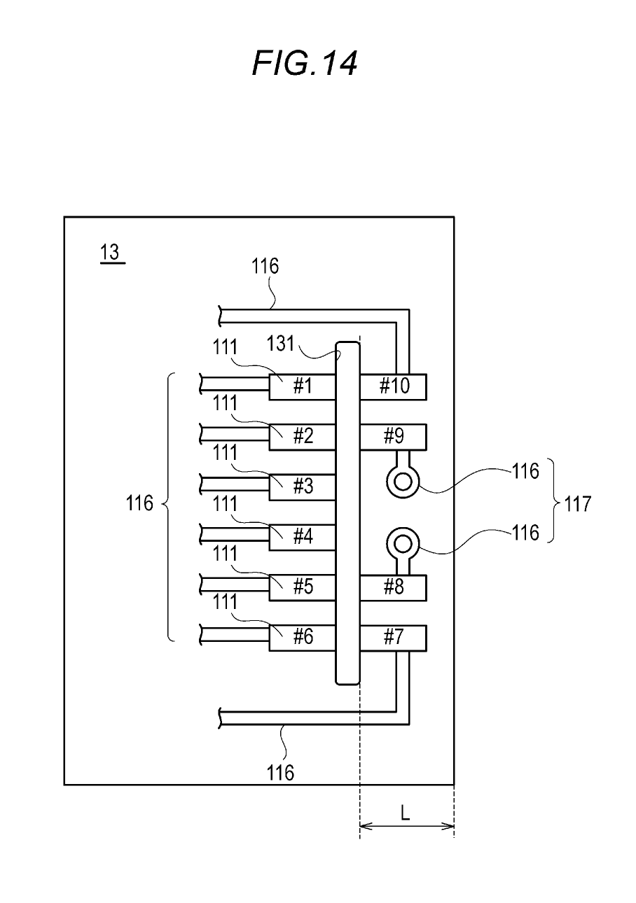

Next, an example having a mounting structure that is effective for making the area around the pad 111 compact in the image sensor unit 1 according to the present invention will be described. FIG. 14 illustrates the area around a plurality of pads 111 (#1 to #10) that are arranged around the long hole 131 in the sensor substrate 13 according to the present example. Note that, in the present example also, the pads 111 are connected by solders 110 to respectively corresponding external connection pads 322. A lead wiring pattern 116 for connecting with a circuit that is formed on the sensor substrate 13 is connected to each pad 111.

In this example, in particular, the pads 111 are arranged in a manner in which some pads 111 have been thinned out, and the lead wiring pattern 116 is formed in the thinned-out region. More specifically, pads 111 that are numbered #1 to #6 are arranged on one side of the long hole 131 (inner side of the sensor substrate 13), and pads 111 that are numbered #7, #8, and #9, #10 are arranged on the other side of the long hole 131 (end side of the sensor substrate 13). That is, as illustrated in the drawing, on the other side of the long hole 131, pads have been thinned out from a region corresponding to the pads 111 numbered #3 and #4, and the lead wiring pattern 116 is formed in the thinned-out region 117. An arrangement pattern of, so to speak, missing teeth is formed by thinning out the pads 111 in this way.

By forming the lead wiring pattern 116 in the thinned-out region 117 of the pads 111 in this way, extension of the lead wiring pattern 116 to the end side of the sensor substrate 13 is avoided, and a length L from the long hole 131 to the end of the sensor substrate 13 is shortened. That is, the length in the longitudinal direction of the sensor substrate 13 can be shortened, and in this way the image sensor unit 1 can be reduced in size.

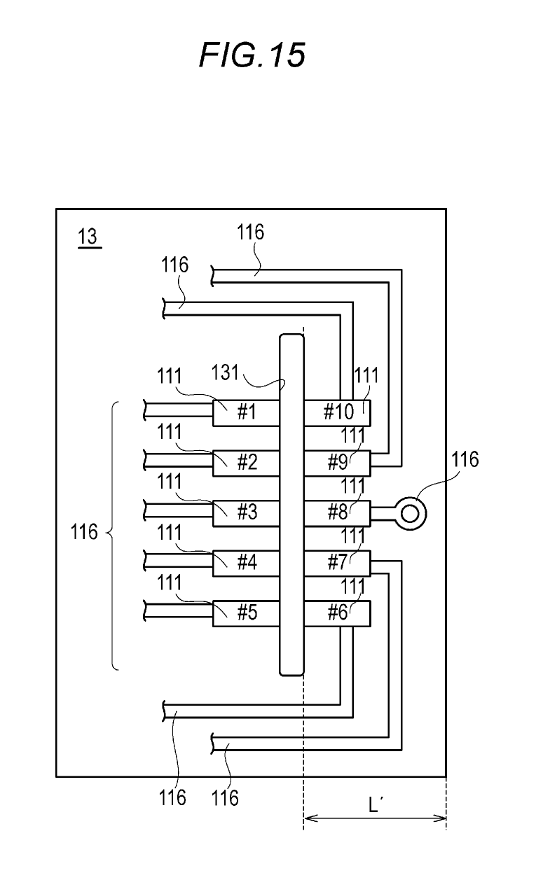

In the conventional image sensor unit 1 that does not have the missing-teeth arrangement pattern of the pads 111, for example, as illustrated in FIG. 15, pads 111 that are numbered #1 to #5 and #6 to #10 are arranged on both sides of the long hole 131, respectively. In this example, the lead wiring patterns 116 connected to the pads 111 numbered #7 to #9 are longer by two steps and extend to the end side of the sensor substrate 13, and a length L′ from the long hole 131 to the end of the sensor substrate 13 must become longer, and this is a factor that hinders reduction of the size of the image sensor unit 1.

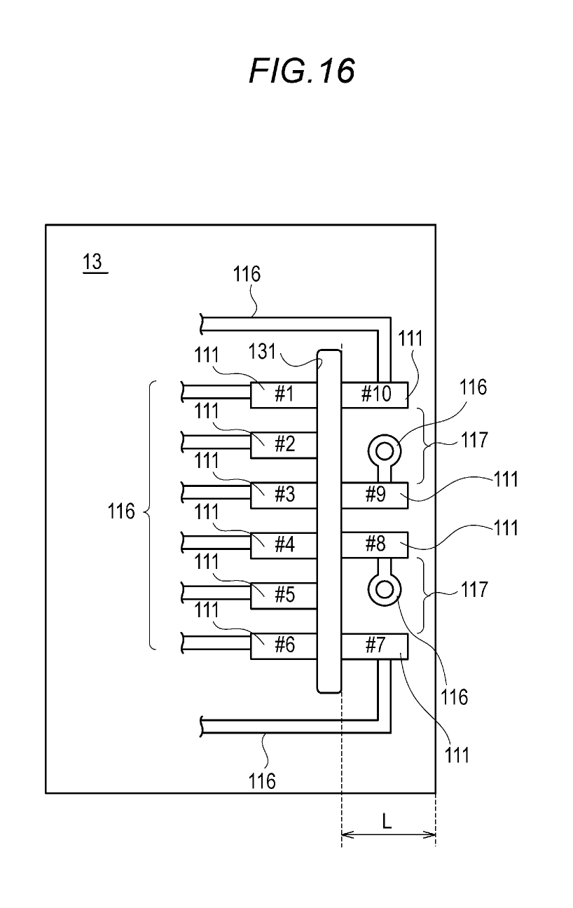

FIG. 16 illustrates another example of a missing-teeth arrangement pattern of the pads 111. In this example, on the other side of the long hole 131, pads 111 are thinned out from regions that correspond to the pads 111 numbered #2 and #5 on the one side, and the lead wiring patterns 116 are formed in these thinned-out regions 117. In this case also, similarly to the above described case, extension of the lead wiring pattern 116 to the end side of the sensor substrate 13 is avoided, the length L from the long hole 131 to the end of the sensor substrate 13 is shortened, and the length in the longitudinal direction of the sensor substrate 13, and thus the size of the image sensor unit 1 can be reduced.

While a detailed illustration has been described in detail for this example also, in this case the aforementioned gap g between the pad 111 and the long hole 131 can be eliminated and the aforementioned cut-out portion 113 can be formed with respect to the pad 111, and furthermore, the peripheral portion thereof can be covered by the resist layer 115.

As described above, when mounting the light source substrate 32 on the sensor substrate 13 in the image sensor unit 1, by improving the configuration of the pad 111 itself and the area around the pad 111, soldering for connecting the two components to each other can be made stable and appropriate, and the electrical connectivity and bonding strength can be improved. In addition, by suitably setting the arrangement pattern of the pads 111, a reduction in size can be achieved. In these ways, smooth and correct operation of the image sensor unit 1 is secured and maintained, and an effective contribution is made to reducing the size thereof.

(Paper Sheet Distinguishing Apparatus)

Next, the paper sheet distinguishing apparatus 5 to which the image sensor unit 1 is applied will be described referring to FIG. 17. FIG. 17 is a schematic sectional view showing a configuration of the paper sheet distinguishing apparatus 5, illustrating a cross section taken along a plane perpendicular to the main-scan direction. The paper sheet distinguishing apparatus 5 emits light to a bill or the like as the object of illumination P to read light from the bill and uses the read light to distinguish the type or authenticity of the bill.

As illustrated in FIG. 17, the paper sheet distinguishing apparatus 5 includes the image sensor unit 1, conveyor rollers 51 that convey the bill, and an image distinguishing portion 52 as distinguishing means that is connected by wire to the connector 15. A conveyance path A for conveying a bill that is sandwiched by the conveyor rollers 51 in the reading direction (sub-scan direction) over the image sensor unit 1 through the cover member 11 is set in the paper sheet distinguishing apparatus 5. Note that a focal point on the bill side of the light condenser 12 is set at the center of the conveyance path A.

The operation of the paper sheet distinguishing apparatus 5 having this configuration is as follows. Based on the operation described above, the image sensor unit 1 applied to the paper sheet distinguishing apparatus 5 reads a visible light image of a predetermined pattern provided on the bill and reads an infrared image of the bill. The image distinguishing portion 52 then determines the authenticity of the bill by comparing a genuine bill image, which is obtained by emitting visible light and infrared light to a prepared genuine bill, with the visible light image and the infrared image of the bill to be determined in the authenticity determination. This is because the genuine bill includes a region in which the images obtained under visible light and under infrared light are different. Note that, the parts not described and not illustrated can be the same as in a conventional paper sheet distinguishing apparatus. Further, a configuration may also be adopted in which the image distinguishing portion 52 is provided on the sensor substrate 13.

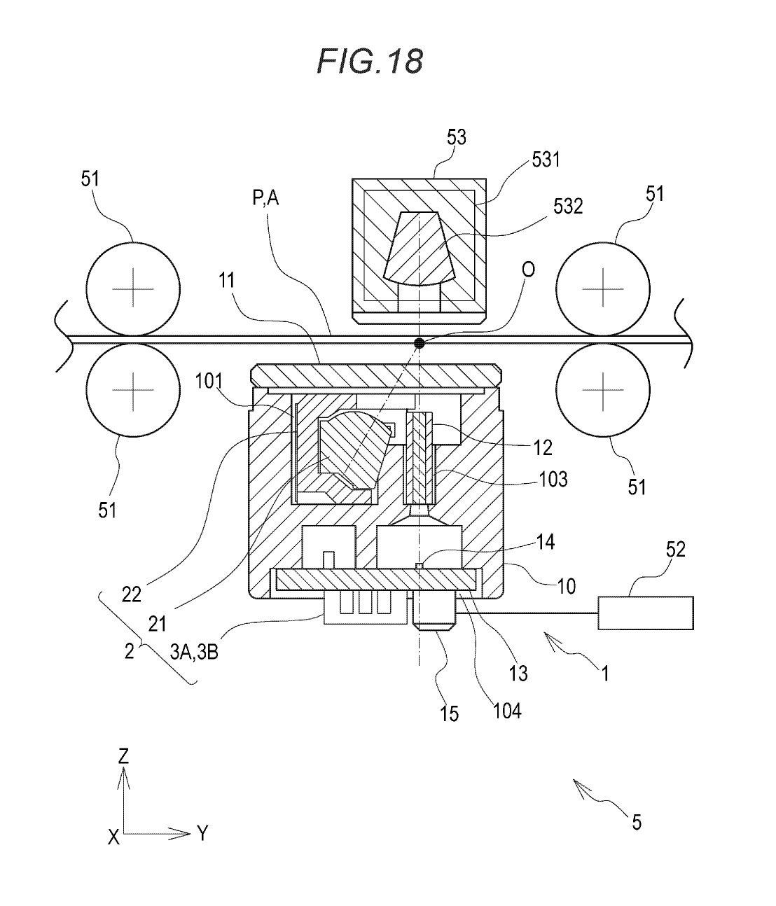

FIG. 18 is a schematic sectional view showing a configuration of the paper sheet distinguishing apparatus 5 further including a transmission illumination device 53. The transmission illumination device 53 includes a light source module 531 and a light guide 532. The light source module 531 and the light guide 532 of the transmission illumination device 53 have the same configurations as those of the light source modules 3A and 3B and the light guide 21 described above. The transmission illumination device 53 is arranged at a position facing the image sensor unit 1 so as to be capable of emitting light to a bill. Particularly, the transmission illumination device 53 is arranged so that an optical axis of the light emitted from the emission surface of the light guide 532 thereof and an optical axis of the light condenser 12 of the image sensor unit 1 coincide. In some cases, these optical axes do not coincide, and are set in an oblique direction.

The operations of the paper sheet distinguishing apparatus 5 with the configuration are as follows. The light source modules 3A and 3B incorporated into the image sensor unit 1 and the light source module 531 of the transmission illumination device 53 sequentially turn on the LED elements of the visible light of each color and the infrared light. The light emitted from the light guide 21 of the illumination device 2 of the image sensor unit 1 to the bill is reflected by the surface of the bill and enters the light condenser 12, and an image is thereby formed on the light receiving surface of the image sensor 14. The image sensor 14 converts the formed optical image to an electric signal to acquire a visible light image and an infrared image based on the reflected light from the bill. Meanwhile, the light emitted from the transmission illumination device 53 to the bill is transmitted through the bill to enter the light condenser 12 of the image sensor unit 1, and an image is formed on the light receiving surface of the image sensor 14. The image sensor 14 converts the formed optical image to an electric signal to acquire a visible light image and an infrared image based on the transmitted light from the bill.

The illumination device 2 of the image sensor unit 1 and the transmission illumination device 53 alternately repeat, in a short time, the operation of emitting light to the bill and detecting the reflected light and the transmitted light. Based on the operation, the image sensor unit 1 reads a visible light image of a predetermined pattern (for example, a hologram) provided on the bill and also reads an infrared image of the bill. According to this configuration, the paper sheet distinguishing apparatus 5 can read the visible light image and the infrared image obtained based on the reflected light and the transmitted light of the bill.

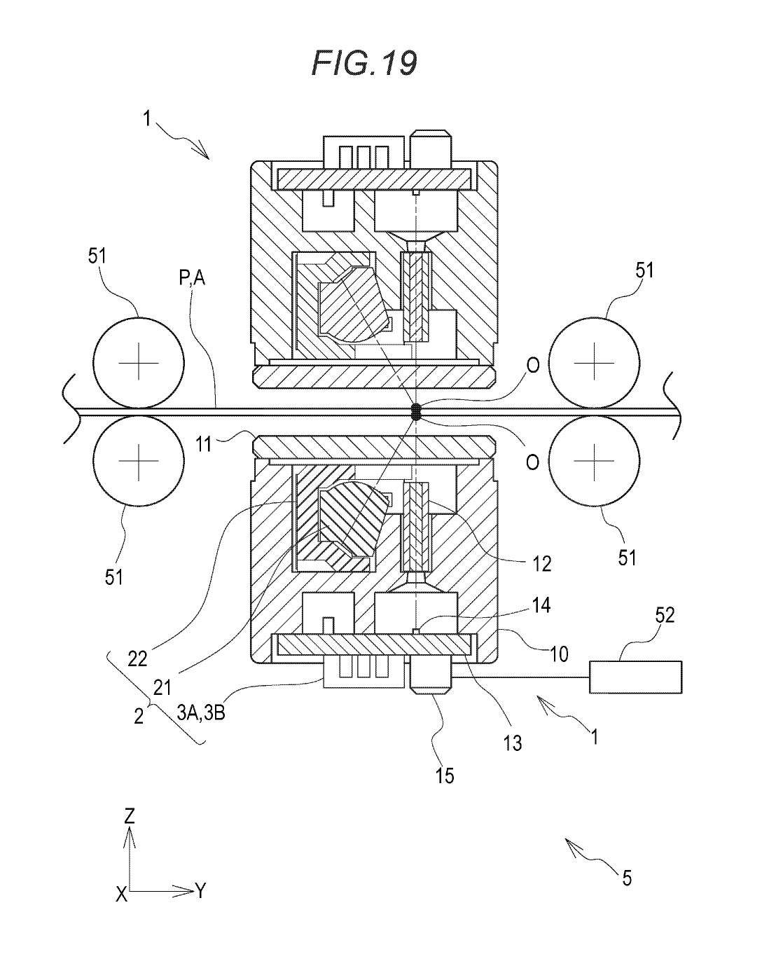

The paper sheet distinguishing apparatus 5 may also include two sets of the image sensor unit 1. FIG. 19 is a sectional view that schematically illustrates the configuration of the paper sheet distinguishing apparatus 5 including two sets of the image sensor unit 1. As illustrated in FIG. 19, the two sets of the image sensor unit 1 are arranged to face each other across the conveyance path A of the bill. The two sets of the image sensor unit 1 are arranged so that the light emitted from the light guide 21 of one of the image sensor units 1 and transmitted through the bill enters the light condenser 12 of the other image sensor unit 1.

The operations of the paper sheet distinguishing apparatus 5 with this configuration are as follows. The light source modules 3A and 3B that are incorporated into the two sets of image sensor units 1 sequentially turn on the LED elements of the visible light of each color and the infrared light. The light emitted from the illumination device 2 of one of the image sensor units 1 to the bill is reflected by the surface of the bill and enters the light condenser 12 of the one image sensor unit 1, and an image is formed on the light receiving surface of the image sensor 14 of the one image sensor unit 1. The image sensor 14 of the one image sensor unit 1 converts the formed optical image to an electric signal to acquire a visible light image and an infrared image based on the reflected light from the bill. Further, the light emitted from the illumination device 2 of the one image sensor unit 1 to the bill is transmitted through the bill and enters the light condenser 12 of the other image sensor unit 1, and an image is formed on the light receiving surface of the image sensor 14 of the other image sensor unit 1. The image sensor 14 of the other image sensor unit 1 converts the formed optical image to an electric signal to acquire a visible light image and an infrared image based on the transmitted light from the bill. According to this configuration, the paper sheet distinguishing apparatus 5 can read reflected images of both surfaces of the bill and can also read transmitted images.

Note that although a configuration that reads a visible light image and an infrared image of a bill by emitting visible light and infrared light is described in the present embodiment, the present invention is not limited to such a configuration. For example, a configuration that emits ultraviolet light may be adopted. Further, although a configuration has been described in which a bill is applied as the object of illumination P, the type of the paper sheet is not limited. For example, various kinds of securities or ID cards or the like can be applied.

In addition, by application the above described image sensor unit 1 to the aforementioned paper sheet distinguishing apparatus 5, smooth and correct operation thereof is secured and maintained, and a reduction in the size thereof can be realized.

(Image Reading Apparatus (Part 1))

FIG. 20 is a perspective view illustrating a configuration of a flatbed-type scanner 7A as an image reading apparatus to which the image sensor unit 1 that is an embodiment of the present invention can be applied. The scanner 7A includes a housing 71a, a platen glass 72 as an object of illumination placing part, the image sensor unit 1, a driving mechanism that drives the image sensor unit 1, a circuit board 73a, and a platen cover 74. The platen glass 72 as the object of illumination placing part is composed of a transparent plate such as a glass plate, and is mounted to the upper face of the housing 71a. The platen cover 74 is attached in a manner allowing opening and closing thereof to the housing 71a through a hinge mechanism or the like so as to cover the object of illumination P that has been placed on the platen glass 72. The image sensor unit 1, the driving mechanism for driving the image sensor unit 1, and the circuit board 73a are housed inside the housing 71a.

The driving mechanism includes a holding member 750, a guide shaft 751, a drive motor 752 and a wire 754. The holding member 750 surrounds and holds the image sensor unit 1. The guide shaft 751 movably guides the holding member 750 in the reading direction (sub-scan direction) along the platen glass 72. The drive motor 752 and the holding member 750 are coupled through the wire 754, and the holding member 750 that holds the image sensor unit 1 is driven in the sub-scan direction by a driving force of the drive motor 752. The image sensor unit 1 reads an original or the like as the object of illumination P that was placed on the platen glass 72, while moving in the sub-scan direction under the driving force of the drive motor 752. Thus, the object of illumination P is read while relatively moving the image sensor unit 1 and the object of illumination P.

An image processing circuit that performs predetermined image processing on an image that was read by the image sensor unit 1, a control circuit that controls each portion of the scanner 7A including the image sensor unit 1, and a power supply circuit that supplies power to each portion of the scanner 7A and the like are constructed on the circuit board 73a.

(Image Reading Apparatus (Part 2))

FIG. 21 is a cross-sectional schematic view that illustrates a configuration of a sheet-feed type scanner 7B as an image reading apparatus to which the image sensor unit 1 that is an embodiment of the present invention can be applied. As illustrated in FIG. 21, the scanner 7B includes a housing 71b, the image sensor unit 1, conveyor rollers 76, a circuit board 73b and a cover glass 77. A driving mechanism that is not illustrated in the drawings causes the conveyor rollers 76 to rotate so as to sandwich the object of illumination P therebetween and convey the object of illumination P. The cover glass 77 is provided so as to cover the upper side of the image sensor unit 1. A control circuit that controls each portion of the scanner 7B including the image sensor unit 1, and a power supply circuit that supplies power to each portion of the scanner 7B and the like are constructed on the circuit board 73b.

The scanner 7B reads the object of illumination P by means of the image sensor unit 1 while conveying the object of illumination P in the reading direction (sub-scan direction) by means of the conveyor rollers 76. That is, the scanner 7B reads the object of illumination P while relatively moving the image sensor unit 1 and the object of illumination P. Note that although an example in which the scanner 7B reads one side of the object of illumination P is illustrated in FIG. 21, a configuration may also be adopted in which two image sensor units 1 are provided so as to face each other across the conveyance path A of the object of illumination, and which reads both sides of the object of illumination P.

Although the scanners 7A and 7B have been described above with reference to FIG. 20 and FIG. 21 as examples of an image reading apparatus using the image sensor unit 1 to which the present invention can be applied, the configurations or kinds of image reading apparatuses that use the image sensor unit 1 are not limited to the scanners 7A and 7B described above.

In addition, by application the above described image sensor unit 1 to the aforementioned image reading apparatus, smooth and correct operation thereof is secured and maintained, and a reduction in the size thereof can be realized.

(Image Forming Apparatus)

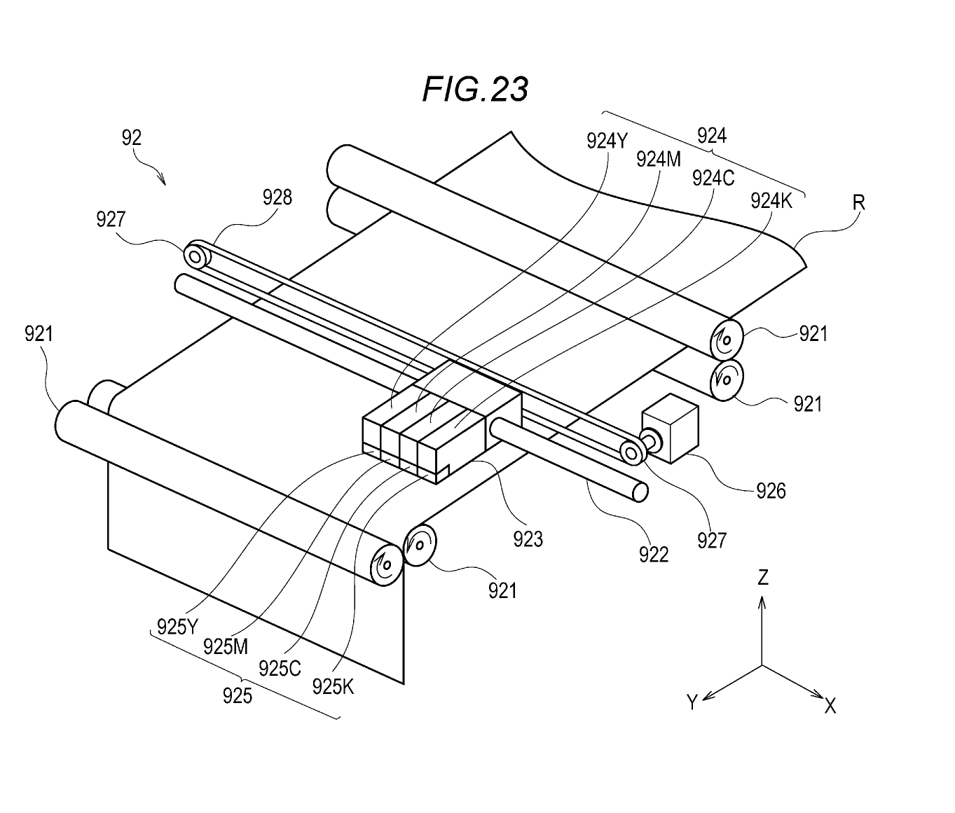

Next, an image forming apparatus 9 that is an embodiment of the present invention is described referring to FIG. 22 and FIG. 23. The image sensor unit 1 that is an embodiment of the present invention is applied to the image forming apparatus 9 that is an embodiment of the present invention. FIG. 22 is an external perspective view of the image forming apparatus 9 as an embodiment of the present invention. FIG. 23 is a perspective view illustrated by extracting an image forming portion 92 provided in a housing 91 of the image forming apparatus 9 that is an embodiment of the present invention. As illustrated in FIG. 22 and FIG. 23, the image forming apparatus 9 is a compound machine (MFP: multifunction printer) of a flatbed-type scanner and an inkjet printer. The image forming apparatus 9 includes an image reading portion 93 as image reading means that reads an image, and the image forming portion 92 as image forming means that forms an image. The image sensor unit 1 is incorporated into the image reading portion 93 of the image forming apparatus 9. Configurations common to those of the image reading apparatus described above can be applied to the image reading portion 93 of the image forming apparatus 9. Accordingly, a description of the configurations common to those of the image reading apparatus will not be repeated.

As illustrated in FIG. 22, an operation portion 94 is provided in the image forming apparatus 9. The operation portion 94 includes a display portion 941 that displays an operation menu and various messages and the like, and various operation buttons 942 for operating the image forming apparatus 9. Further, as illustrated in FIG. 23, the image forming portion 92 is provided inside the housing 91 of the image forming apparatus 9. The image forming portion 92 includes conveyor rollers 921, a guide shaft 922, an inkjet cartridge 923, a motor 926 and a pair of timing pulleys 927. The conveyor rollers 921 rotate by means of a driving force of a driving source, and convey a printing paper R as a recording medium in the sub-scan direction. The guide shaft 922 is a rod-shaped member, and is fixed to the housing 91 of the image forming apparatus 9 so that the axis thereof is parallel to the main-scan direction of the printing paper R.

The inkjet cartridge 923 can move back and forth in the main-scan direction of the printing paper R by sliding on the guide shaft 922. The inkjet cartridge 923 includes, for example, ink tanks 924 (924C, 924M, 924Y and 924K) that are equipped with cyan C, magenta M, yellow Y and black K ink, and discharge heads 925 (925C, 925M, 925Y and 925K) that are provided in the respective ink tanks 924. One of the pair of timing pulleys 927 is attached to a rotating shaft of the motor 926. The pair of timing pulleys 927 are provided at positions that are separated from each other in the main-scan direction of the printing paper R. A timing belt 928 is wound around the pair of timing pulleys 927 in parallel with the pair of timing pulleys 927, and a predetermined section thereof is coupled to the inkjet cartridge 923.

The image reading portion 93 of the image forming apparatus 9 converts an image read by the image sensor unit 1 to an electric signal in a form that is suitable for printing. The image forming portion 92 of the image forming apparatus 9 drives the conveyor rollers 921, the motor 926 and the inkjet cartridge 923 based on the electric signal converted by the image sensor unit 1 of the image reading portion 93 and forms an image on the printing paper R. In addition, the image forming portion 92 of the image forming apparatus 9 can form an image based on an electric signal input from the outside. The same configurations as those of various well-known printers can be applied to the configurations and operation of the image forming portion 92 in the image forming apparatus 9. Therefore, the details will not be described. Although an inkjet-type image forming apparatus has been described as the image forming portion 92, the type can be any type, such as an electrophotographic type, a thermal transfer type, and a dot impact type.

Although embodiments and examples of the present invention have been described in detail above, the embodiments and examples described above are just specific examples of embodiments of the present invention. The technical scope of the present invention is not limited to the embodiments and examples described above. Many modifications can be made to the embodiments and examples without departing from the spirit of the present invention.

In the above described embodiments, an example is described of the image sensor unit 1 in which the light source substrate 32 on which a light source is mounted as one circuit board and the sensor substrate 13 on which an image sensor is mounted as another circuit board are connected to each other through the solder 110. The present invention is not limited to the case of the image sensor unit 1, and can similarly be applied with respect to electronics devices having a mounting structure that connects respective connection terminals of two or more kinds of circuit boards to each other through the solder 110. Further, although the illumination device 2 including the light source and the light guide 21 is used as a reflection reading light source for the original P, the illumination apparatus may be used as a transmission reading light source.

The present invention can be effectively used for an illumination device, for an image sensor unit to which the illumination device is applied, and for an image reading apparatus and an image forming apparatus to which the image sensor unit is applied (for example, image scanner, facsimile, copying machine, and compound machine).

### REFERENCE SIGNS LIST

1 Image sensor unit
5 Paper sheet distinguishing apparatus
7A, 7B Image reading apparatus
9 Image forming apparatus
11 Cover member
12 Light condenser
13 Sensor substrate
14 Image sensor
21 Light guide
31 Light source
32 Light source substrate
111 Pad
110 Solder
113 Cut-out portion
115 Resist layer
116 Lead wiring pattern
117 Thinned-out region
131 Long hole (insertion opening)
322 External connection pad (external connection terminal)

1. An image sensor unit that reads light emitted to an object of illumination, comprising:
a light source substrate including an external connection terminal,
a light source that is mounted on the light source substrate,
a light guide that emits light towards the object of illumination,
a light condenser that focuses light from the object of illumination,
an image sensor that receives light that is focused by the light condenser, and converts the light to an electric signal, and
a sensor substrate on which the light source substrate and the image sensor are mounted,
wherein:
the sensor substrate includes an insertion opening for inserting the light source substrate, and
a plurality of pads arranged along the insertion opening; and
a plurality of the pads and the external connection terminal are connected through a solder, and a tip of the pads reaches an opening edge of the insertion opening.

2. The image sensor unit according to claim 1, having, in a tip portion of the pads, a burr clearance portion that is formed at least on either side in a width direction thereof.

3. The image sensor unit according to claim 1, having a resist layer that is coated onto a surface of the sensor substrate on which the pads are arranged, wherein a peripheral portion of the pads is covered by the resist layer.

4. The image sensor unit according to claim 1, having a thinned-out region in which some of the pads that are arranged along the insertion opening are thinned out, and a lead wiring pattern that is formed in the thinned-out region.

5. The image sensor unit according to claim 4, wherein the thinned-out region is set at an end side of the sensor substrate.

6. A paper sheet distinguishing apparatus that reads light from an object of illumination while relatively moving an image sensor unit and the object of illumination,
the image sensor unit comprising:
a light source substrate including an external connection terminal,
a light source that is mounted on the light source substrate,
a light guide that emits light towards the object of illumination,
a light condenser that focuses light from the object of illumination,
an image sensor that receives light that is focused by the light condenser, and converts the light to an electric signal, and
a sensor substrate on which the light source substrate and the image sensor are mounted,
wherein:
the sensor substrate includes an insertion opening for inserting the light source substrate, and
a plurality of pads arranged along the insertion opening; and
a plurality of the pads and the external connection terminal are connected through a solder, and a tip of the pads reaches an opening edge of the insertion opening,
wherein the image sensor unit has a thinned-out region in which some of the pads that are arranged along the insertion opening are thinned out, and a lead wiring pattern that is formed in the thinned-out region, and
wherein the thinned-out region is set at an end side of the sensor substrate.

7. An image reading apparatus that reads light from an object of illumination while relatively moving an image sensor unit and the object of illumination, the image sensor unit comprising:
a light source substrate including an external connection terminal,
a light source that is mounted on the light source substrate,
a light guide that emits light towards the object of illumination,
a light condenser that focuses light from the object of illumination,
an image sensor that receives light that is focused by the light condenser, and converts the light to an electric signal, and
a sensor substrate on which the light source substrate and the image sensor are mounted,
wherein:
the sensor substrate includes an insertion opening for inserting the light source substrate, and
a plurality of pads arranged along the insertion opening; and
a plurality of the pads and the external connection terminal are connected through a solder, and a tip of the pads reaches an opening edge of the insertion opening,
wherein the image sensor unit has a thinned-out region in which some of the pads that are arranged along the insertion opening are thinned out, and a lead wiring pattern that is formed in the thinned-out region, and
wherein the thinned-out region is set at an end side of the sensor substrate.

8. An image forming apparatus, comprising:
image reading means that reads light from an object of illumination while relatively moving an image sensor unit and the object of illumination, and
image forming means that forms an image on a recording medium;
the image sensor unit comprising:
a light source substrate including an external connection terminal,
a light source that is mounted on the light source substrate,
a light guide that emits light towards the object of illumination,
a light condenser that focuses light from the object of illumination,
an image sensor that receives light that is focused by the light condenser, and converts the light to an electric signal, and
a sensor substrate on which the light source substrate and the image sensor are mounted,
wherein:
the sensor substrate includes an insertion opening for inserting the light source substrate, and
a plurality of pads arranged along the insertion opening; and
a plurality of the pads and the external connection terminal are connected through a solder, and a tip of the pads reaches an opening edge of the insertion opening,
wherein the image sensor unit has a thinned-out region in which some of the pads that are arranged along the insertion opening are thinned out, and a lead wiring pattern that is formed in the thinned-out region, and
wherein the thinned-out region is set at an end side of the sensor substrate.

9. A method of manufacturing an image sensor unit that reads light emitted to an object of illumination and that comprises:
a light source substrate including an external connection terminal,
a light source that is mounted on the light source substrate,
a light guide that emits light towards the object of illumination,
a light condenser that focuses light from the object of illumination,
an image sensor that receives light that is focused by the light condenser, and converts the light to an electric signal, and
a sensor substrate on which the light source substrate and the image sensor are mounted;
the method of manufacturing comprising:
previously setting a formation region for an insertion opening of the light source substrate on the sensor substrate,
extending a tip portion of a pad as far as an inner side of the formation region for the insertion opening, and forming the pad, and
cutting the formation region for the insertion opening together with the tip portion of the pad by means of a cutting tool.

10. The method of manufacturing an image sensor unit according to claim 9, wherein a burr clearance portion is formed at least in a downstream-side area in a feeding direction of the cutting tool in a tip portion on the insertion opening side of the pad.

11. The method of manufacturing an image sensor unit according to claim 9, wherein a resist layer is coated onto a surface of the sensor substrate on which the pad is arranged, and a peripheral portion of the pad is covered by the resist layer.

12. The method of manufacturing an image sensor unit according to claim 9, wherein some of the pads that are arranged along the insertion opening are thinned out, and a lead wiring pattern is formed in a thinned-out region of the pads.

13. The method of manufacturing an image sensor unit according to claim 12, wherein the thinned-out region is set at an end side of the sensor substrate.
